(19) United States
(12) Patent Application Publication
(10) Pub. No.: US 2025/0172639 A1
(43) Pub. Date: May 29, 2025

(54) MAGNETIC FIELD SENSING MODULE AND MAGNETIC SENSOR

(71) Applicant: SUZHOU NOVOSENSE MICROELECTRONICS CO., LTD., Suzhou (CN)

(72) Inventor: Fute YUAN, Suzhou (CN)

(73) Assignee: SUZHOU NOVOSENSE MICROELECTRONICS CO., LTD., Suzhou (CN)

(21) Appl. No.: 18/948,631

(22) Filed: Nov. 15, 2024

(30) Foreign Application Priority Data
Nov. 29, 2023 (CN) 202311610118.1

(51) Int. Cl. G01R 33/09; G01R 33/00

(52) U.S. Cl. CPC G01R 33/09; G01R 33/0005

(57) ABSTRACT

The present application discloses a magnetic field sensing module and a magnetic sensor. The magnetic field sensing module comprises: a first magnetoresistor and a second magnetoresistor coupled in series; in a first state, the first magnetoresistor is applied with a signal magnetic field carrying direction information and a first excitation magnetic field, and the second magnetoresistor is applied with the signal magnetic field and a second excitation magnetic field; in a second state, the first magnetoresistor is applied with the signal magnetic field and a third excitation magnetic field, and the second magnetoresistor is applied with the signal magnetic field and a fourth excitation magnetic field. The magnetic field sensing module provided by the present application can be used to realize the expansion of the output period and enhance the richness of the magnetic field signal content that can be obtained.

### TECHNICAL FIELD

The present application belongs to the field of magnetic field detection technology, and in particular, relates to a magnetic field sensing module and a magnetic sensor.

### BACKGROUND

Magnetic field detection technology has a wide range of applications, particularly in the fields of industry and automotive. It can be used to measure a rotation angle of objects such as gear shafts or mechanical devices, as well as position information and route information of devices like valves. For the former, a magnetic encoder can be configured to generate a magnetic field, driving an object to be measured to rotate synchronously with the magnetic field, and a magnetic sensor can be configured to measure a rotation angle and a rotation speed.

In the prior art, magnetic sensors are typically configured to support a fixed-period signal output, considering both sensitivity and cost. Taking angle sensing as an example, the output signal can be set to a 180-degree period. However, in some special conditions, there is a need to sense data over a larger range, such as a 360-degree angle change. Traditional magnetic sensors and their magnetic field sensing modules cannot support such sensing, requiring replacement with sensors or sensing modules that can provide a larger fixed-period signal output.

However, such sensors have disadvantages in terms of sensitivity and cost. The existing technical solutions also have problems such as needing to arrange sensing components unidirectionally, resulting in misalignment with a geometric center of the object to be measured, or causing large errors in magnetic field component distribution due to different sensing directions from the main magnetic field signal. Additionally, using vertical Hall devices further reduces sensitivity. Therefore, how to expand the sensing module based on fixed-period signal output to support larger-period signal output is an urgent technical problem in this field.

### SUMMARY

One of the objectives of the present application is to provide a magnetic field sensing module to solve a technical problem of fixed signal output periods in existing magnetic field sensing modules, which limits the acquisition of magnetic field information content and fails to support larger-period signal output.

Another objective of the present application is to provide a magnetic sensor.

To achieve the above objectives, one embodiment of the present application provides a magnetic field sensing module, comprising: a first magnetoresistor and a second magnetoresistor coupled in series, forming an output node between the first magnetoresistor and the second magnetoresistor, where a first current direction at the first magnetoresistor and a second current direction at the second magnetoresistor are set at an angle; in a first state, the first magnetoresistor is applied with a signal magnetic field carrying direction information and a first excitation magnetic field, and the second magnetoresistor is applied with the signal magnetic field and a second excitation magnetic field; in a second state, the first magnetoresistor is applied with the signal magnetic field and a third excitation magnetic field, and the second magnetoresistor is applied with the signal magnetic field and a fourth excitation magnetic field; a direction of the first excitation magnetic field is opposite to a direction of the third excitation magnetic field, and/or a direction of the second excitation magnetic field is opposite to a direction of the fourth excitation magnetic field.

To achieve the above objectives, one embodiment of the present application provides a magnetic field sensing module, comprising: a first magnetoresistor and a second magnetoresistor coupled in series, forming a first output node between the first magnetoresistor and the second magnetoresistor, where a first current direction at the first magnetoresistor and a second current direction at the second magnetoresistor are set at an angle; a third magnetoresistor and a fourth magnetoresistor coupled in series, forming a second output node between the third magnetoresistor and the fourth magnetoresistor, where a third current direction at the third magnetoresistor and a fourth current direction at the fourth magnetoresistor are set at an angle; the third magnetoresistor and the fourth magnetoresistor are coupled in parallel with the first magnetoresistor and the second magnetoresistor; the first magnetoresistor is applied with a signal magnetic field carrying direction information and a first excitation magnetic field, the second magnetoresistor is applied with the signal magnetic field and a second excitation magnetic field; the third magnetoresistor is applied with the signal magnetic field and a third excitation magnetic field, the fourth magnetoresistor is applied with the signal magnetic field and a fourth excitation magnetic field; a direction of the first excitation magnetic field is opposite to a direction of the third excitation magnetic field, and/or a direction of the second excitation magnetic field is opposite to a direction of the fourth excitation magnetic field.

To achieve the above objectives, one embodiment of the present application provides a magnetic sensor, comprising a magnetic field sensing module according to any one of technical solutions in the present application and an excitation coil for generating an excitation magnetic field at the magnetic field sensing module; a magnetoresistive element in the magnetic field sensing module is arranged in a first direction or a second direction, and excitation coil is arranged on at least one side of the magnetic field sensing module in a third direction; the third direction is perpendicular to both the first direction and the second direction.

To achieve the above objectives, one embodiment of the present application provides a magnetic sensor, comprising: an angle sensor, which obtains sensing direction information for a signal magnetic field distributed in a second numerical interval, and actual direction information of the signal magnetic field is distributed in a first numerical interval, where a range of the first numerical interval is greater than a range of the second numerical interval; a magnetic field sensing module according to any one of technical solutions in the present application, configured to form a difference signal containing several zero crossings; a signal processing circuit, coupled to an output node of the magnetic field sensing module, configured at least to generate a square wave signal based on the difference signal; and an output processing circuit, coupled to the signal processing circuit, configured to match the sensing direction information to the first numerical interval based on the square wave signal, so that the sensing direction information is consistent with the actual direction information.

Compared with the prior art, a magnetic field sensing module provided by the present application, on the one hand, sets at least two groups of magnetoresistors with different current directions, which respond to a signal magnetic field and generate outputs in different sensitivity directions as a combined output; simultaneously applies excitation magnetic fields to different magnetoresistors while applying the signal magnetic field, creating differences in magnetization directions between the magnetoresistors. Due to periodic variation of the signal magnetic field, the difference further expands magnetic signal content obtained, especially identifying boundary points of an actual change period, thereby breaking the limitation of the magnetic field sensing module's own sensing period to support larger-period sensing.

### BRIEF DESCRIPTION OF THE DRAWINGS

FIG. 1 shows a structural diagram of the magnetic field sensing module in one embodiment of the present application.

FIG. 2 shows a structural diagram of the magnetic field sensing module in a first state in one embodiment of the present application.

FIG. 3 shows a structural diagram of the magnetic field sensing module in a second state in one embodiment of the present application.

FIG. 4 shows a state curve diagram of the magnetic field sensing module in one embodiment of the present application.

FIG. 5 shows a difference output curve diagram of the magnetic field sensing module in one embodiment of the present application.

FIG. 6 shows a structural diagram of the magnetic field sensing module in a first state in another embodiment of the present application.

FIG. 7 shows a structural diagram of the magnetic field sensing module in a second state in another embodiment of the present application.

FIG. 8 shows a state curve diagram of the magnetic field sensing module in another embodiment of the present application.

FIG. 9 shows a difference output curve diagram of the magnetic field sensing module in another embodiment of the present application.

FIG. 10 shows a structural diagram of the magnetic field sensing module in yet another embodiment of the present application.

FIG. 11 shows a structural diagram of the magnetic field sensing module in yet another embodiment of the present application.

FIG. 12 shows a difference output curve diagram of the magnetic field sensing module in yet another embodiment of the present application.

FIG. 13 shows a structural diagram of the magnetic sensor in one embodiment of the present application.

FIG. 14 shows a cross-sectional view taken along section line R1 in FIG. 13 in one embodiment of the present application.

FIG. 15 shows a cross-sectional view taken along section line R1 in FIG. 13 in another embodiment of the present application.

FIG. 16 shows a structural diagram of the magnetic sensor in yet another embodiment of the present application.

FIG. 17 shows a circuit diagram of the magnetic sensor in one embodiment of the present application.

FIG. 18 shows an output curve diagram of components of the magnetic sensor in one embodiment of the present application.

FIG. 19 shows a circuit diagram of one embodiment of the magnetic sensor in one embodiment of the present application.

FIG. 20 shows a circuit diagram of another embodiment of the magnetic sensor in one embodiment of the present application.

### DETAILED DESCRIPTION

The present application will be described in detail below with reference to the specific embodiments shown in the drawings. However, these embodiments do not limit the present application. Structural, methodological, or functional modifications made by those skilled in the art based on these embodiments are included in the scope of protection of the present application.

The present application provides a magnetic field sensing module for sensing magnetic field information. When the applied signal magnetic field changes periodically, the magnetic field sensing module outputs corresponding magnetic field information with the same or different periods. An output period of the magnetic field sensing module and the richness of the magnetic field information the magnetic field sensing module supports typically depend on the structural configuration of the magnetic field sensing module. When the output period of the magnetic field sensing module is sufficiently wide or the content the magnetic field sensing module supports is sufficiently rich, even if part of data is not needed during computation, the part of data can be avoided through operations such as filtering, discarding, or reusing without affecting the final result. However, when the output period of the magnetic field sensing module is narrow and the content the magnetic field sensing module supports is sparse, the consequences are irreparable. Therefore, the magnetic field sensing module provided by the present application aims to improve the structure and the method of applying the corresponding magnetic field, so that the magnetic field sensing module can provide a wider output period and richer magnetic field information.

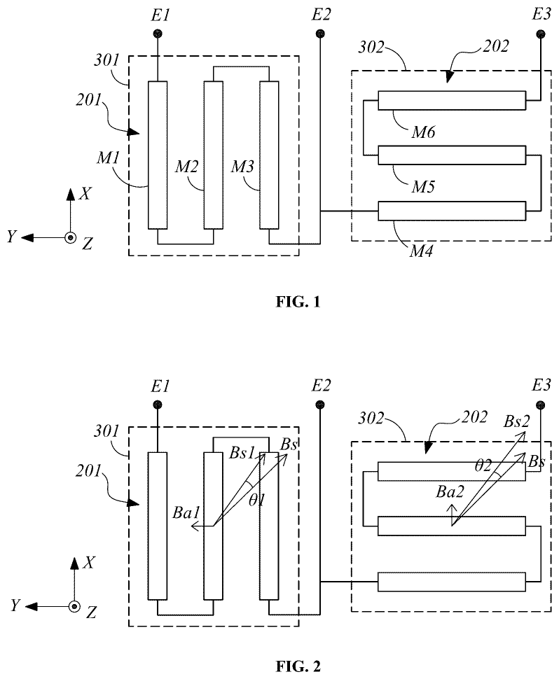

As shown in FIG. 1 to FIG. 3, the magnetic field sensing module provided by the present application includes a first magnetoresistor 201 and a second magnetoresistor 202.

The first magnetoresistor 201 and the second magnetoresistor 202 can each comprise at least one magnetosensitive resistor (also known as a magnetoresistive element), defined as a resistive element sensitive to magnetism and exhibiting a magnetoresistive effect. Of course, in other embodiments, the definition of the magnetosensitive resistor can be replaced by other components sensitive to magnetic field changes and having a clear magnetic sensing direction.

In an embodiment, the first magnetoresistor 201 includes a first magnetoresistive element M1, a second magnetoresistive element M2, and a third magnetoresistive element M3 coupled in series. In an example, the first magnetoresistive element M1, the second magnetoresistive element M2, and the third magnetoresistive element M3 have a same magnetoresistive effect coefficient and/or have a same magnetic sensitivity direction.

The first magnetoresistive element M1 extends in a first direction. The second magnetoresistive element M2 extends in the first direction. The third magnetoresistive element M3 extends in the first direction. In an embodiment, the first direction refers to an X direction and an opposite direction of the X direction as shown in FIG. 1 to FIG. 3.

In an embodiment, the first magnetoresistive element M1 extends from a first end of the first magnetoresistive element M1 to a second end of the first magnetoresistive element M1 in the opposite direction of the X direction; the second end of the first magnetoresistive element M1 is coupled to a first end of the second magnetoresistive element M2; the second magnetoresistive element M2 extends from the first end of the second magnetoresistive element M2 to a second end of the second magnetoresistive element M2 in the X direction; the second end of the second magnetoresistive element M2 is coupled to a first end of the third magnetoresistive element M3; the third magnetoresistive element M3 extends from the first end of the third magnetoresistive element M3 to a second end of the third magnetoresistive element M3 in the opposite direction of the X direction.

When a current is passed through the first magnetoresistor 201, the position of the current input and the extension direction of the magnetoresistive elements determine the current direction at the corresponding magnetoresistive element. For example, when a current is input at the first end of the first magnetoresistive element M1, the first magnetoresistive element M1, the second magnetoresistive element M2, and the third magnetoresistive element M3 each form their own current directions according to their own extension directions mentioned above. In summary, a first current direction consistent with the first direction will be formed at the first magnetoresistor 201.

In an embodiment, the second magnetoresistor 202 includes a fourth magnetoresistive element M4, a fifth magnetoresistive element M5, and a sixth magnetoresistive element M6 coupled in series. In an example, the fourth magnetoresistive element M4, the fifth magnetoresistive element M5, and the sixth magnetoresistive element M6 have a same magnetoresistive effect coefficient and/or have a same magnetic sensitivity direction.

The fourth magnetoresistive element M4 extends in a second direction. The fifth magnetoresistive element M5 extends in the second direction. The sixth magnetoresistive element M6 extends in the second direction. In an embodiment, the second direction refers to a Y direction and an opposite direction of the Y direction as shown in FIG. 1 to FIG. 3.

In an embodiment, the fourth magnetoresistive element M4 extends from a first end of the fourth magnetoresistive element M4 to a second end of the fourth magnetoresistive element M4 in the opposite direction of the Y direction; the second end of the fourth magnetoresistive element M4 is coupled to a first end of the fifth magnetoresistive element M5; the fifth magnetoresistive element M5 extends from the first end of the fifth magnetoresistive element M5 to a second end of the fifth magnetoresistive element M5 in the Y direction; the second end of the fifth magnetoresistive element M5 is coupled to a first end of the sixth magnetoresistive element M6; the sixth magnetoresistive element M6 extends from the first end of the sixth magnetoresistive element M6 to a second end of the sixth magnetoresistive element M6 in the opposite direction of the Y direction.

When a current is passed through the second magnetoresistor 202, the position of the current input and the extension direction of the magnetoresistive elements determine the current direction at the corresponding magnetoresistive element. For example, when a current is input at the first end of the fourth magnetoresistive element M4, the fourth magnetoresistive element M4, the fifth magnetoresistive element M5, and the sixth magnetoresistive element M6 each form their own current directions according to their own extension directions mentioned above. In summary, a second current direction consistent with the second direction will be formed at the second magnetoresistor 202.

A first node E1 is set at the first magnetoresistor 201; a third node E3 is set at the second magnetoresistor 202. One of the first node E1 and the third node E3 is configured to couple a power supply voltage Vd; the other of the first node E1 and the third node E3 is configured to couple a reference ground Gnd.

An output node is set between the first magnetoresistor 201 and the second magnetoresistor 202. For example, the second node E2 in the FIG. 1 to FIG. 3 can be configured to be the output node. The first magnetoresistor 201 and the second magnetoresistor 202 coupled in series can form a half-bridge structure to generate a half-bridge signal output at the output node.

The first current direction at the first magnetoresistor 201 is set at an angle to the second current direction at the second magnetoresistor 202. In an embodiment, the first current direction is perpendicular to the second current direction.

In the magnetic field sensing module provided by the present application, by superimposing an excitation magnetic field while applying a signal magnetic field, a magnetization direction formed at the magnetoresistive element due to the signal magnetic field is deflected, resulting in different resistance values between the magnetoresistive elements. An output of the magnetic field sensing module corresponds to different angle ranges, thereby deforming. Thus, the magnetic field sensing module can have sensitivity to periods other than its original output period, particularly enabling it to distinguish between the original output period and an extended output period, thereby supporting the sensing of a larger period range and enhancing the richness of the magnetic field information that can be obtained by the magnetic field sensing module.

Such excitation magnetic fields can be formed by a magnetic field generation module. If different excitation magnetic fields need to be applied to different magnetoresistors, different magnetic field generation modules can be respectively set at different resistors. The magnetic field generation module can be an independent component or a part of a conductor section of structures like coils.

For example, a first magnetic field generation module 301 can be set at the first magnetoresistor 201 to generate a first excitation magnetic field Ba1 and/or a third excitation magnetic field Ba3 corresponding to the first magnetoresistor 201. For example, a second magnetic field generation module 302 can be set at the second magnetoresistor 202 to generate a second excitation magnetic field Ba2 and/or a fourth excitation magnetic field Ba4 corresponding to the second magnetoresistor 202.

In a first state, as shown in FIG. 2, the first magnetoresistor 201 is applied with a signal magnetic field carrying direction information. The signal magnetic field forms a signal magnetization direction Bs at the first magnetoresistor 201. The first magnetoresistor 201 is applied with the first excitation magnetic field Ba1; the first excitation magnetic field Ba1 causes the signal magnetization direction Bs to deflect by a first angle θ1, forming a first excitation magnetization direction Bs1.

In a first state, as shown in FIG. 2, the second magnetoresistor 202 is applied with a signal magnetic field carrying direction information. The signal magnetic field forms a signal magnetization direction Bs at the second magnetoresistor 202. The second magnetoresistor 202 is applied with the second excitation magnetic field Ba2; the second excitation magnetic field Ba2 causes the signal magnetization direction Bs to deflect by a second angle θ2, forming a second excitation magnetization direction Bs2.

As shown in FIG. 4, when the signal magnetic field is a magnetic field with fixed field strength but continuously changing direction, if no excitation magnetic field is applied, the magnetic field sensing module presents an output like a standard state curve state0, with a 180-degree output period and symmetric amplitude. When the excitation magnetic field is applied corresponding to the first state, the magnetic field sensing module presents an output like a first state curve state1. It can be seen that, compared to the standard state curve state0, under an action of the excitation magnetic field, the curve formed by the output data of the magnetic field sensing module is deformed. For example, the action of the excitation magnetic field results in a larger amplitude of the curve in a 0-degree to 90-degree interval, and then the amplitude of the curve decreases in a 0-degree to 360-degree interval. Thus, distinctions between intervals can be formed within a 360-degree output period, and the curve formed by the output data contains more magnetic field information.

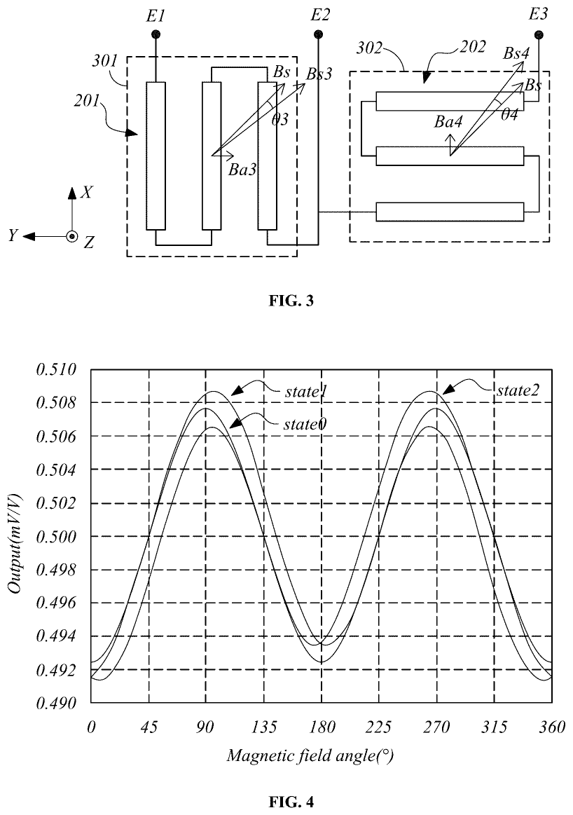

In a second state, as shown in FIG. 3, the first magnetoresistor 201 is applied with a signal magnetic field carrying direction information. The signal magnetic field forms a signal magnetization direction Bs at the first magnetoresistor 201. The first magnetoresistor 201 is applied with the third excitation magnetic field Ba3; the third excitation magnetic field Ba3 causes the signal magnetization direction Bs to deflect by a third angle θ3, forming a third excitation magnetization direction Bs3.

In a second state, as shown in FIG. 3, the second magnetoresistor 202 is applied with a signal magnetic field carrying direction information. The signal magnetic field forms a signal magnetization direction Bs at the second magnetoresistor 202. The second magnetoresistor 202 is applied with the fourth excitation magnetic field Ba4; the fourth excitation magnetic field Ba4 causes the signal magnetization direction Bs to deflect by a fourth angle θ4, forming a fourth excitation magnetization direction Bs4.

As shown in FIG. 4, when the signal magnetic field is a magnetic field with fixed field strength but continuously changing direction, and the excitation magnetic field is applied corresponding to the second state, the magnetic field sensing module presents an output like a second state curve state2. It can be seen that, compared to the standard state curve state0, under the action of the excitation magnetic field, the curve formed by the output data of the magnetic field sensing module is deformed. For example, the action of the excitation magnetic field results in a smaller amplitude of the curve in a 0-degree to 90-degree interval, and then the amplitude of the curve increases in a 0-degree to 360-degree interval. Thus, distinctions between intervals can be formed within a 360-degree output period, and the curve formed by the output data contains more magnetic field information.

In an embodiment, a direction of the first excitation magnetic field Ba1 is opposite to a direction of the third excitation magnetic field Ba3. As such, the outputs of the magnetic field sensing module in the first state and the second state will show opposite amplitude variation trends, as illustrated in FIG. 4. Specifically, in the first state, the first state curve state1 shows a maximum amplitude in a 0-degree to 90-degree interval and then decreases, while in the second state, the second state curve state2 shows a minimum amplitude in a 0-degree to 90-degree interval and then increases. Thus, a 360-degree output period can be formed. In a preferable embodiment, field strengths of the first excitation magnetic field Ba1 and the third excitation magnetic field Ba3 are equal, and field strengths of the second excitation magnetic field Ba2 and the fourth excitation magnetic field Ba4 are equal, so that the first state curve state1 and the second state curve state2 are symmetrical.

In an embodiment, actual direction information of the signal magnetic field is distributed within a first numerical interval, and sensing direction information of an angle sensor cooperating with the magnetic field sensing module is distributed within a second numerical interval. The range of the first numerical interval is greater than the range of the second numerical interval. An output node signal of the magnetic field sensing module is configured to match the sensing direction information to the first numerical interval.

For example, the first numerical interval is from 0 degrees to 360 degrees, and an output period supported by the angle sensor or the magnetic field sensing module without the above configuration is 180 degrees, the second numerical interval is from 0 degrees to 180 degrees, According to the magnetic field sensing module provided by the present application, at least a curve corresponding to the output node signal of the magnetic field sensing module will be deformed, so that the range before and after 180 degrees presents a distinction in at least one dimension (e.g., amplitude), forming an equivalent output from 0 degrees to 360 degrees. In this way, the output node signal can be configured to match the corresponding sensing direction information to an interval from 0 degrees to 360 degrees, thereby expanding the range of the output node signal or expanding the output range of the angle sensor, enabling it to support the detection of a larger angle range without modifying the structure of the angle sensor.

The magnetic field sensing module forms a corresponding first output node signal in the first state; in an example, the first output node signal corresponds to the first state curve state1. The magnetic field sensing module forms a corresponding second output node signal in the second state; in an example, the second output node signal corresponds to the second state curve state2.

The first output node signal and the second output node signal are configured to form a corresponding difference signal; this difference signal can be obtained through separate subtraction operations or by forming a connection based on circuit coupling relationships between the two output node signals.

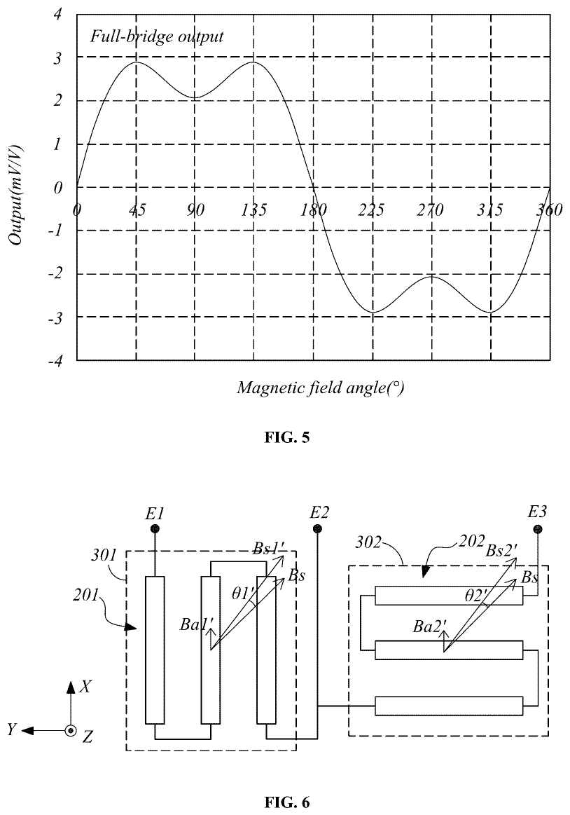

The difference signal presents a difference output curve as shown in FIG. 5. This difference output curve has a 360-degree output period and can provide corrections to an output of the magnetic field sensing module itself or an output of the corresponding angle sensor, matching the magnetic field sensing module or the angle sensor to a larger output interval from 0 degrees to 360 degrees.

Specifically, the difference signal includes several zero crossings; for example, the difference output curve shown in FIG. 5 has a zero crossing at 180 degrees of the period, equivalent to dividing the output interval from 0 degrees to 360 degrees into two parts: 0 degrees to 180 degrees and 180 degrees to 360 degrees. The latter part is an extension of the original 180-degree output period. Based on the zero crossing, a sensing output of the magnetic field sensing module itself or the sensing direction information of the angle sensor corresponding to the magnetic field sensing module can be matched to a larger first numerical interval. In an embodiment, the first numerical interval includes the numerical interval from 0 degrees to 360 degrees; for example, the first numerical interval can be the numerical interval from 0 degrees to 540 degrees, or from 0 degrees to 720 degrees, etc.

Regarding a relationship between directions of the excitation magnetic fields: in an embodiment, a direction of the first excitation magnetic field Ba1 is opposite to a direction of the third excitation magnetic field Ba3; a direction of the second excitation magnetic field Ba2 is the same as a direction of the fourth excitation magnetic field Ba4. In an example, a direction of the first excitation magnetic field Ba1 points in the Y direction, a direction of the third excitation magnetic field Ba3 points in an opposite direction of the Y direction; a direction of the second excitation magnetic field Ba2 and a direction of the fourth excitation magnetic field Ba4 point in the X direction.

Regarding a relationship between current directions: the first current direction is perpendicular to the second current direction.

Regarding a relationship between the direction of the excitation magnetic field and the current direction: in an embodiment, a direction of the first excitation magnetic field Ba1 and a direction of the third excitation magnetic field Ba3 are perpendicular to the first current direction; a direction of the second excitation magnetic field Ba2 and a direction of the fourth excitation magnetic field Ba4 are perpendicular to the second current direction.

In an embodiment, a direction of the second excitation magnetic field Ba2 is opposite to a direction of the fourth excitation magnetic field Ba4. In an embodiment, a direction of the first excitation magnetic field Ba1 is the same as a direction of the third excitation magnetic field Ba3. The formed technical solutions and technical effects refer to the previous text and will not be repeated here.

In an embodiment, a direction of the first excitation magnetic field Ba1 is opposite to a direction of the third excitation magnetic field Ba3, and a direction of the second excitation magnetic field Ba2 is opposite to a direction of the fourth excitation magnetic field Ba4.

In the first state, as shown in FIG. 6, the first magnetoresistor 201 is applied with a signal magnetic field carrying direction information. The signal magnetic field forms a signal magnetization direction Bs at the first magnetoresistor 201. The first magnetoresistor 201 is applied with another first excitation magnetic field Ba1′; another first excitation magnetic field Ba1′ causes the signal magnetization direction Bs to deflect by another first angle θ1′, forming another first excitation magnetization direction Bs1′.

In the first state, as shown in FIG. 6, the second magnetoresistor 202 is applied with a signal magnetic field carrying direction information. The signal magnetic field forms a signal magnetization direction Bs at the second magnetoresistor 202. the second magnetoresistor 202 is applied with another second excitation magnetic field Ba2′; another second excitation magnetic field Ba2′ causes the signal magnetization direction Bs to deflect by another second angle θ2′, forming another second excitation magnetization direction Bs2′.

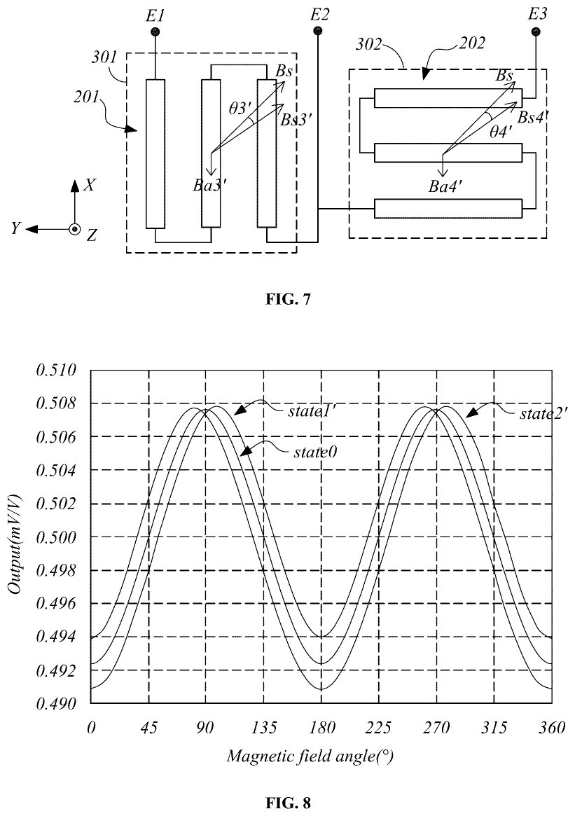

As shown in FIG. 8, when the signal magnetic field is a magnetic field with fixed field strength but continuously changing direction, if no excitation magnetic field is applied, the magnetic field sensing module presents an output like a standard state curve state0, with a 180-degree output period and symmetric amplitude. When the excitation magnetic field is applied corresponding to the first state, the magnetic field sensing module presents an output like another first state curve state1′. It can be seen that, compared to the standard state curve state0, under an action of the excitation magnetic field, the curve formed by the output data of the magnetic field sensing module is deformed. For example, the action of the excitation magnetic field results in a larger amplitude of the curve in a 0-degree to 90-degree interval and a 270-degree to 360-degree interval, while the amplitude of the curve is smaller in a 90-degree to 270-degree interval. Thus, distinctions between intervals can be formed within a 360-degree output period, and the curve formed by the output data contains more magnetic field information.

In a second state, as shown in FIG. 7, the first magnetoresistor 201 is applied with a signal magnetic field carrying direction information. The signal magnetic field forms a signal magnetization direction Bs at the first magnetoresistor 201. The first magnetoresistor 201 is applied with another third excitation magnetic field Ba3′; another third excitation magnetic field Ba3′ causes the signal magnetization direction Bs to deflect by another third angle θ3′, forming another third excitation magnetization direction Bs3′.

In a second state, as shown in FIG. 7, the second magnetoresistor 202 is applied with a signal magnetic field carrying direction information. The signal magnetic field forms a signal magnetization direction Bs at the second magnetoresistor 202. The second magnetoresistor 202 is applied with another fourth excitation magnetic field Ba4′; another fourth excitation magnetic field Ba4′ causes the signal magnetization direction Bs to deflect by another fourth angle θ4′, forming another fourth excitation magnetization direction Bs4′.

As shown in FIG. 8, when the signal magnetic field is a magnetic field with fixed field strength but continuously changing direction, and the excitation magnetic field is applied corresponding to the second state, the magnetic field sensing module presents an output like another second state curve state2′. It can be seen that, compared to the standard state curve state0, under the action of the excitation magnetic field, the curve formed by the output data of the magnetic field sensing module is deformed. For example, the action of the excitation magnetic field results in a smaller amplitude of the curve in a 0-degree to 90-degree interval and a 270-degree to 360-degree interval, while the amplitude of the curve is larger in a 90-degree to 270-degree interval. Thus, distinctions between intervals can be formed within a 360-degree output period, and the curve formed by the output data contains more magnetic field information.

Furthermore, another first state curve state1′ and another second state curve state2′ can also assist in extending the output period.

In an embodiment, the field strengths of another first excitation magnetic field Ba1′ and another third excitation magnetic field Ba3′ are equal, and the field strengths of another second excitation magnetic field Ba2′ and another fourth excitation magnetic field Ba4′ are equal. In this case, another first state curve state1′ and another second state curve state2′ are symmetrical with respect to a same axis of symmetry.

In the embodiment, it is also possible to match the output of the magnetic field sensing module or the output of the cooperating angle sensor to a larger first numerical interval based on the deformation of the output node signal, which will not be repeated here.

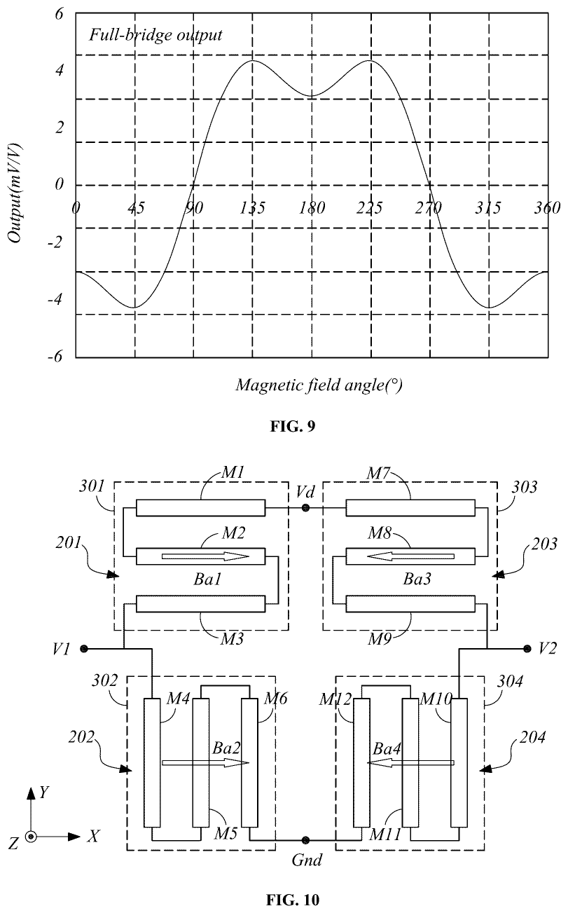

Another difference signal is formed between another first output node signal corresponding to another first state curve state1′ and another second output node signal corresponding to another second state curve state2′. This other difference signal presents another difference output curve as shown in FIG. 9. Another difference output curve has a 360-degree output period and can provide corrections to an output of the magnetic field sensing module itself or an output of the corresponding angle sensor, matching the magnetic field sensing module or the angle sensor to a larger output interval from 0 degrees to 360 degrees.

Specifically, another difference signal includes several zero crossings; for example, another difference output curve shown in FIG. 9 has zero crossings at 90 degrees and 270 degrees of the period, equivalent to dividing the output interval from 0 degrees to 360 degrees into three parts: 0 degrees to 90 degrees, 90 degrees to 270 degrees, and 270 degrees to 360 degrees (or, it can be understood as dividing into two parts: 90 degrees to 270 degrees and 270 degrees to 90 degrees of the next period), thus forming an extension of the original 180-degree output period.

Regarding a relationship between directions of the excitation magnetic fields: in an embodiment, a direction of another first excitation magnetic field Ba1′ is opposite to a direction of another third excitation magnetic field Ba3′; a direction of another second excitation magnetic field Ba2′ is opposite to a direction of another fourth excitation magnetic field Ba4′. In an example, a direction of another first excitation magnetic field Ba1′ points in the X direction, a direction of another third excitation magnetic field Ba3′ points in an opposite direction of the X direction; a direction of another second excitation magnetic field Ba2′ points in the Y direction, and a direction of another fourth excitation magnetic field Ba4′ points in the opposite direction of the Y direction.

Regarding a relationship between current directions: the first current direction is perpendicular to the second current direction.

Regarding a relationship between the direction of the excitation magnetic field and the current direction: in an embodiment, a direction of another first excitation magnetic field Ba1′ and a direction of another third excitation magnetic field Ba3′ are parallel to the first current direction; a direction of another second excitation magnetic field Ba2′ and a direction of another fourth excitation magnetic field Ba4′ are perpendicular to the second current direction. Specifically, the first current direction can point in the X direction or the opposite direction of the X direction; therefore, for the magnetoresistive elements with the current direction pointing in the X direction, the current direction of the magnetoresistive elements is the same as the direction of another first excitation magnetic field Ba1′; for the magnetoresistive elements with the current direction pointing in the opposite direction of the X direction, the current direction of the magnetoresistive elements is the same as the direction of another third excitation magnetic field Ba3′.

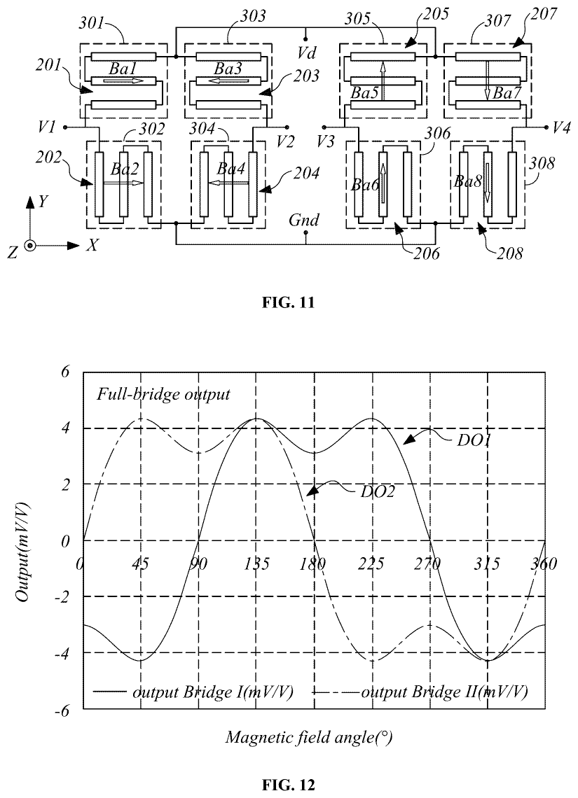

As shown in FIG. 11, the magnetic field sensing module provided by the present application includes a seventh magnetoresistor 207 and an eighth magnetoresistor 208.

The seventh magnetoresistor 207 and the eighth magnetoresistor 208 can each be composed of at least one magnetosensitive resistor (also known as a magnetoresistive element). In an embodiment, the seventh magnetoresistor 207 includes three magnetoresistive elements coupled in series, and the eighth magnetoresistor 208 includes three magnetoresistive elements coupled in series. The corresponding relationship between the current direction on the magnetoresistive elements and the current direction of the magnetoresistor has been described previously and will not be repeated here.

Based on this, the seventh magnetoresistor 207 forms a seventh current direction consistent with the first direction; the eighth magnetoresistor 208 forms an eighth current direction consistent with the second direction.

The seventh magnetoresistor 207 and the eighth magnetoresistor 208 are coupled in series.

The magnetic field sensing module also includes a first magnetoresistor 201 and a second magnetoresistor 202 coupled in series. The seventh magnetoresistor 207 and the eighth magnetoresistor 208 are coupled in parallel with the first magnetoresistor 201 and the second magnetoresistor 202; specifically, a magnetoresistive branch formed by the seventh magnetoresistor 207 and the eighth magnetoresistor 208 coupled in series is coupled in parallel with another magnetoresistive branch formed by the first magnetoresistor 201 and the second magnetoresistor 202 coupled in series.

A node for coupling one of the power supply voltage Vd and the reference ground Gnd is set at the first magnetoresistor 201 and the seventh magnetoresistor 207; another node for coupling the other one of the power supply voltage Vd and the reference ground Gnd is set at the second magnetoresistor 202 and the eighth magnetoresistor 208.

An output node is set between the first magnetoresistor 201 and the second magnetoresistor 202, such as a first output node V1; an output node is set between the seventh magnetoresistor 207 and the eighth magnetoresistor 208, such as a fourth output node V4. The first magnetoresistor 201 and the second magnetoresistor 202 coupled in series can form a half-bridge structure, and the seventh magnetoresistor 207 and the eighth magnetoresistor 208 coupled in series can form another half-bridge structure, thereby generating dual half-bridge signal outputs at the first output node V1 and the fourth output node V4.

The seventh current direction at the seventh magnetoresistor 207 is set at an angle to the eighth current direction at the eighth magnetoresistor 208. In an embodiment, the seventh current direction is perpendicular to the eighth current direction.

In the magnetic field sensing module provided by the present application, an excitation magnetic field can be superimposed while applying a signal magnetic field to support sensing over a larger period range and enhance the richness of the magnetic field information that can be obtained.

Such excitation magnetic fields can be formed by a magnetic field generation module, For example, a seventh magnetic field generation module 307 can be set at the seventh magnetoresistor 207 to generate a seventh excitation magnetic field Ba7 and/or a fifth excitation magnetic field Ba5 corresponding to the seventh magnetoresistor 207. For example, an eighth magnetic field generation module 308 can be set at the eighth magnetoresistor 208 to generate an eighth excitation magnetic field Ba8 and/or a sixth excitation magnetic field Ba6 corresponding to the eighth magnetoresistor 208.

In the first state, the first magnetoresistor 201, the second magnetoresistor 202, the seventh magnetoresistor 207, and the eighth magnetoresistor 208 are applied with a signal magnetic field carrying direction information, forming a signal magnetization direction.

At the same time, the first magnetoresistor 201 is applied with the first excitation magnetic field Ba1, causing the signal magnetization direction at the first magnetoresistor 201 to deflect and form a first excitation magnetization direction; the second magnetoresistor 202 is applied with the second excitation magnetic field Ba2, causing the signal magnetization direction at the second magnetoresistor 202 to deflect and form a second excitation magnetization direction; the seventh magnetoresistor 207 is applied with the seventh excitation magnetic field Ba7, causing the signal magnetization direction at the seventh magnetoresistor 207 to deflect and form a seventh excitation magnetization direction; the eighth magnetoresistor 208 is applied with the eighth excitation magnetic field Ba8, causing the signal magnetization direction at the eighth magnetoresistor 208 to deflect and form a eighth excitation magnetization direction.

In the second state, the first magnetoresistor 201, the second magnetoresistor 202, the seventh magnetoresistor 207, and the eighth magnetoresistor 208 are applied with a signal magnetic field carrying direction information, forming a signal magnetization direction.

At the same time, the first magnetoresistor 201 is applied with the third excitation magnetic field Ba3, causing the signal magnetization direction to deflect and form the third excitation magnetization direction; the second magnetoresistor 202 is applied with the fourth excitation magnetic field Ba4, causing the signal magnetization direction to deflect and form the fourth excitation magnetization direction; the seventh magnetoresistor 207 is applied with the fifth excitation magnetic field Ba5, causing the signal magnetization direction to deflect and form a fifth excitation magnetization direction; the eighth magnetoresistor 208 is applied with the sixth excitation magnetic field Ba6, causing the signal magnetization direction to deflect and form a sixth excitation magnetization direction.

In an embodiment, the direction of the first excitation magnetic field Ba1 is opposite to the direction of the third excitation magnetic field Ba3.

In an embodiment, the direction of the second excitation magnetic field Ba2 is opposite to the direction of the fourth excitation magnetic field Ba4. In an embodiment, both configurations of the excitation magnetic field directions defined above are satisfied simultaneously.

In an embodiment, a direction of the seventh excitation magnetic field Ba7 is opposite to a direction of the fifth excitation magnetic field Ba5.

In an embodiment, a direction of the eighth excitation magnetic field Ba8 is opposite to a direction of the sixth excitation magnetic field Ba6. In an embodiment, both configurations of the excitation magnetic field directions defined above are satisfied simultaneously.

In an embodiment, all four configurations of the excitation magnetic field directions defined above are satisfied simultaneously.

In an embodiment, the first magnetoresistor 201 and the second magnetoresistor 202 are configured to form a first output node signal in the first state; the first magnetoresistor 201 and the second magnetoresistor 202 are configured to form a second output node signal in the second state; the seventh magnetoresistor 207 and the eighth magnetoresistor 208 are configured to form a fourth output node signal in the first state; the seventh magnetoresistor 207 and the eighth magnetoresistor 208 are configured to form a third output node signal in the second state.

The first output node signal and the second output node signal form a corresponding first difference signal; the fourth output node signal and the third output node signal form a corresponding second difference signal. The difference signals mentioned above can be obtained through separate subtraction operations or by forming a connection based on circuit coupling relationships between two output node signals.

The first difference signal presents a first difference output curve DO1 as shown in FIG. 12; the second difference signal presents a second difference output curve DO2 as shown in FIG. 12. Both of the two difference signals have a 360-degree output period; in an embodiment, both can have a fixed phase difference.

In an embodiment, when data at a zero crossing of the first difference output curve DO1 is unstable and prone to jumping, output of the magnetic field sensing module can be based on the data at a point corresponding to the zero crossing in the second difference output curve DO2 at this time; when data at a zero crossing of the second difference output curve DO2 is unstable and prone to jumping, output of the magnetic field sensing module can be based on the data at a point corresponding to the zero crossing in the first difference output curve DO1 at this time; thus, the two curves compensate each other, ensuring stability within the 0-degree to 360-degree interval.

In an embodiment, a phase difference between the first difference output curve DO1 and the second difference output curve DO2 is 90 degrees. For example, in FIG. 12, the zero crossing of the first difference output curve DO1 is at 90 degrees or 270 degrees, and at this time, the second difference output curve DO2 has a more stable data output performance; the zero crossing of the second difference output curve DO2 is at 180 degrees, and at this time, the first difference output curve DO1 has a more stable data output performance. Thus, stability is maximized throughout the entire output interval range.

The first difference signal and the second difference signal are configured to match the sensing output of the magnetic field sensing module itself, or sensing direction information of the angle sensor corresponding to the magnetic field sensing module, to the first numerical interval. In an embodiment, the range of the first numerical interval is greater than the range of the second numerical interval supported by the sensing module or angle sensor in the prior art. In an embodiment, the first numerical interval includes a numerical interval from 0 degrees to 360 degrees.

In an embodiment, the first difference signal and the second difference signal can achieve the matching of the first numerical interval through their own zero crossings or the distribution relationship between the two sets of zero crossings; specifically, the expansion from a 180-degree output period to a 360-degree output period can be realized.

Regarding a relationship between the directions of the excitation magnetic fields: in an embodiment, a direction of the seventh excitation magnetic field Ba7 is opposite to a direction of the fifth excitation magnetic field Ba5; a direction of the eighth excitation magnetic field Ba8 is opposite to a direction of the sixth excitation magnetic field Ba6. In an example, a direction of the seventh excitation magnetic field Ba7 points in the opposite direction of the Y direction, a direction of the fifth excitation magnetic field Ba5 points in the Y direction; a direction of the eighth excitation magnetic field Ba8 points in the opposite direction of the Y direction, and a direction of the sixth excitation magnetic field Ba6 points in the Y direction.

In an embodiment, the direction of the first excitation magnetic field Ba1 is opposite to the direction of the third excitation magnetic field Ba3; the direction of the second excitation magnetic field Ba2 is opposite to the direction of the fourth excitation magnetic field Ba4. In an example, the direction of the first excitation magnetic field Ba1 points in the X direction, the direction of the third excitation magnetic field Ba3 points in the opposite direction of the X direction; the direction of the second excitation magnetic field Ba2 points in the X direction, and the direction of the fourth excitation magnetic field Ba4 points in the opposite direction of the X direction.

Regarding the relationship between current directions: in an embodiment, the seventh current direction is perpendicular to the eighth current direction.

In an embodiment, the first current direction is perpendicular to the second current direction.

In an embodiment, the seventh current direction is parallel to the first current direction. In an embodiment, the eighth current direction is parallel to the second current direction.

Regarding the relationship between a direction of the excitation magnetic field and the current direction: in an embodiment, a direction of the fifth excitation magnetic field Ba5 and a direction of the seventh excitation magnetic field Ba7 are perpendicular to the seventh current direction; directions of the sixth excitation magnetic field Ba6 and the eighth excitation magnetic field Ba8 are parallel to the eighth current direction.

In an embodiment, directions of the first excitation magnetic field Ba1 and the third excitation magnetic field Ba3 are parallel to the first current direction; directions of the second excitation magnetic field Ba2 and the fourth excitation magnetic field Ba4 are perpendicular to the second current direction.

It should be emphasized that although FIG. 11 is configured as a schematic in describing the magnetic field sensing module, it does not imply that all components in FIG. 11 must be included in the magnetic field sensing module. For example, only the first magnetoresistor 201, the second magnetoresistor 202, the seventh magnetoresistor 207, and the eighth magnetoresistor 208 are needed to form a dual half-bridge output. In other words, the technical solution provided above can include only the first magnetoresistor 201, the second magnetoresistor 202, the seventh magnetoresistor 207, and the eighth magnetoresistor 208.

Based on the same principle, although the magnetic field sensing module includes the first magnetoresistor 201, the second magnetoresistor 202, the seventh magnetoresistor 207, and the eighth magnetoresistor 208, it does not mean that components such as a third magnetoresistor 203, a fourth magnetoresistor 204, a fifth magnetoresistor 205 and a sixth magnetoresistor 206 must be included between the first magnetoresistor 201, the second magnetoresistor 202, and the seventh magnetoresistor 207, the eighth magnetoresistor 208. The above numbering is only for the convenience of distinguishing and describing and does not limit the importance and quantity. In addition, the numbering of current directions, output nodes, and excitation magnetic fields also does not limit their importance and quantity.

As shown in FIG. 10, a magnetic field sensing module provided by the present application includes a first magnetoresistor 201, a second magnetoresistor 202, a third magnetoresistor 203, and a fourth magnetoresistor 204.

The first magnetoresistor 201, the second magnetoresistor 202, the third magnetoresistor 203, and the fourth magnetoresistor 204 can each be composed of at least one magnetosensitive resistor (also known as a magnetoresistive element). In an embodiment, the first magnetoresistor 201 includes three magnetoresistive elements coupled in series, the second magnetoresistor 202 includes three magnetoresistive elements coupled in series, the third magnetoresistor 203 includes three magnetoresistive elements coupled in series, and the fourth magnetoresistor 204 includes three magnetoresistive elements coupled in series. The corresponding relationship between a current direction on the magnetoresistive elements and a current direction of the magnetoresistor has been described previously and will not be repeated here.

Based on this, a current in a first current direction is formed at the first magnetoresistor 201, a current in a second current direction is formed at the second magnetoresistor 202, a current in a third current direction is formed at the third magnetoresistor 203, and the fourth magnetoresistor 204 forms a fourth current direction.

The first current direction at the first magnetoresistor 201 is set at an angle to the second current direction at the second magnetoresistor 202. In an embodiment, the first current direction is perpendicular to the second current direction.

The third current direction at the third magnetoresistor 203 is set at an angle to the fourth current direction at the fourth magnetoresistor 204. In an embodiment, the third current direction is perpendicular to the fourth current direction.

The first magnetoresistor 201 and the second magnetoresistor 202 are coupled in series; the third magnetoresistor 203 and the fourth magnetoresistor 204 are coupled in series.

The third magnetoresistor 203 and the fourth magnetoresistor 204 are coupled in parallel with the first magnetoresistor 201 and the second magnetoresistor 202. Specifically, a magnetoresistive branch formed by the third magnetoresistor 203 and the fourth magnetoresistor 204 coupled in series is coupled in parallel with another magnetoresistive branch formed by the first magnetoresistor 201 and the second magnetoresistor 202 coupled in series.

A node for coupling one of the power supply voltage Vd and the reference ground Gnd is set at the first magnetoresistor 201 and the third magnetoresistor 203; another node for coupling the other one of the power supply voltage Vd and the reference ground Gnd is set at the second magnetoresistor 202 and the fourth magnetoresistor 204.

An output node is set between the first magnetoresistor 201 and the second magnetoresistor 202, such as a first output node V1; an output node is set between the third magnetoresistor 203 and the fourth magnetoresistor 204, such as a second output node V2. The first magnetoresistor 201 and the second magnetoresistor 202 coupled in series can form a half-bridge structure, and the third magnetoresistor 203 and the fourth magnetoresistor 204 coupled in series can form another half-bridge structure, thereby generating a full-bridge signal output at the first output node V1 and the second output node V2.

In the magnetic field sensing module provided by the present application, an excitation magnetic field can be superimposed while applying a signal magnetic field to support sensing over a larger period range and enhance the richness of the magnetic field information that can be obtained. Additionally, because a full-bridge output is formed, the two magnetoresistive branches are mirror symmetrical and thus do not produce output for the signal magnetic field but only produce output due to the deflection of the magnetization direction caused by the excitation magnetic field, which can more accurately expand the output period of the magnetic field sensing module. Moreover, the two bridge arms correspond to each other, allowing the output curve to be corrected to symmetrically arrange around 0 mV, and cancel out the effects of external interference magnetic fields.

Such excitation magnetic fields can be formed by a magnetic field generation module, For example, a first magnetic field generation module 301 can be set at the first magnetoresistor 201 to generate a first excitation magnetic field Ba1 corresponding to the first magnetoresistor 201. For example, a second magnetic field generation module 302 can be set at the second magnetoresistor 202 to generate a second excitation magnetic field Ba2 corresponding to the second magnetoresistor 202. A third magnetic field generation module 303 can be set at the third magnetoresistor 203 to generate a third excitation magnetic field Ba3 corresponding to the third magnetoresistor 203. A fourth magnetic field generation module 304 can be set at the fourth magnetoresistor 204 to generate a fourth excitation magnetic field Ba4 corresponding to the fourth magnetoresistor 204.

The first magnetoresistor 201, the second magnetoresistor 202, the third magnetoresistor 203, and the fourth magnetoresistor 204 are applied with a signal magnetic field carrying direction information, forming a signal magnetization direction.

At the same time, the first magnetoresistor 201 is applied with the first excitation magnetic field Ba1, causing a signal magnetization direction at the first magnetoresistor 201 to deflect and form a first excitation magnetization direction; the second magnetoresistor 202 is applied with the second excitation magnetic field Ba2, causing the signal magnetization direction at the second magnetoresistor 202 to deflect and form a second excitation magnetization direction;

the third magnetoresistor 203 is applied with the third excitation magnetic field Ba3, causing the signal magnetization direction at the third magnetoresistor 203 to deflect and form a third excitation magnetization direction; the fourth magnetoresistor 204 is applied with the fourth excitation magnetic field Ba4, causing the signal magnetization direction at the fourth magnetoresistor 204 to deflect and form a fourth excitation magnetization direction.

In an embodiment, a direction of the first excitation magnetic field Ba1 is opposite to a direction of the third excitation magnetic field Ba3.

In an embodiment, a direction of the second excitation magnetic field Ba2 is opposite to a direction of the fourth excitation magnetic field Ba4.

In an embodiment, the configurations of the excitation magnetic field directions defined above are satisfied simultaneously.

Thus, while achieving the technical effects provided above, there is no need to configure the first magnetoresistor 201 and the second magnetoresistor 202 to switch between the first state and the second state. The output can be achieved by the comparative outputs among the four sets of magnetoresistors, realizing the expansion of the output period and enhancing the richness of the magnetic field signal content that can be obtained.

Specifically, a difference signal output as shown in FIG. 9 can be obtained simply by coupling the first output node V1 and the second output node V2 directly.

Actual direction information of the signal magnetic field is distributed within a first numerical interval, and sensing direction information of an angle sensor cooperating with the magnetic field sensing module is distributed within a second numerical interval. A range of the first numerical interval is greater than a range of the second numerical interval. An output node signal of the magnetic field sensing module is configured to match the sensing direction information to the first numerical interval.

Specifically, an output node signal of the first output node V1 of the magnetic field sensing module and an output node signal of the second output node V2 are configured to match the sensing direction information to the first numerical interval. In an embodiment, the first output node V1 and the second output node V2 are coupled to form a total output node, and an output node signal at the total output node is configured to match the sensing direction information to the first numerical interval.

The first magnetoresistor 201 and the second magnetoresistor 202 are configured to form a first output node signal; the third magnetoresistor 203 and the fourth magnetoresistor 204 are configured to form a second output node signal. A difference signal is formed between the first output node signal and the second output node signal, preferably directly formed by coupling the nodes.

The difference signal presents a difference output curve as shown in FIG. 9. This difference output curve has a 360-degree output period and can provide corrections to an output of the magnetic field sensing module itself or an output of the corresponding angle sensor, matching the magnetic field sensing module or the angle sensor to a larger output interval from 0 degrees to 360 degrees.

Specifically, the difference signal includes several zero crossings; for example, the difference output curve shown in FIG. 9 has zero crossings at 90 degrees and 270 degrees of the period, equivalent to dividing the output interval from 0 degrees to 360 degrees into three parts: 0 degrees to 90 degrees, 90 degrees to 270 degrees, and 270 degrees to 360 degrees (or it can be understood as dividing into two parts: 90 degrees to 270 degrees and 270 degrees to the next period's 90 degrees). Thus, forming an extension of the original 180-degree output period.

Based on this, the above zero crossings are configured to match the sensing output of the magnetic field sensing module itself, or the sensing direction information of the angle sensor corresponding to the magnetic field sensing module, to the first numerical interval. In an embodiment, the first numerical interval includes a numerical interval from 0 degrees to 360 degrees; for example, the first numerical interval can be the numerical interval from 0 degrees to 540 degrees, or from 0 degrees to 720 degrees, etc.

Regarding a relationship between directions of the excitation magnetic fields: in an embodiment, a direction of the first excitation magnetic field Ba1 is opposite to a direction of the third excitation magnetic field Ba3; a direction of the second excitation magnetic field Ba2 is opposite to a direction of the fourth excitation magnetic field Ba4. In an example, a direction of the first excitation magnetic field Ba1 points in the X direction, a direction of the third excitation magnetic field Ba3 points in an opposite direction of the X direction; a direction of the second excitation magnetic field Ba2 points in the X direction, and a direction of the fourth excitation magnetic field Ba4 points in an opposite direction of the X direction.

Regarding a relationship between current directions: in an embodiment, the first current direction is perpendicular to the second current direction.

In an embodiment, the third current direction is perpendicular to the fourth current direction.

In an embodiment, the third current direction is parallel to the first current direction. In an embodiment, the fourth current direction is parallel to the second current direction.

Regarding a relationship between the direction of the excitation magnetic field and the current direction: in an embodiment, a direction of the first excitation magnetic field Ba1 is parallel to the first current direction; a direction of the second excitation magnetic field Ba2 is perpendicular to the second current direction.

In an embodiment, a direction of the third excitation magnetic field Ba3 is parallel to the third current direction; a direction of the fourth excitation magnetic field Ba4 is perpendicular to the fourth current direction.

In an embodiment, the first magnetoresistor 201 includes a first magnetoresistive element M1, a second magnetoresistive element M2, and a third magnetoresistive element M3 coupled in series. In an example, the first magnetoresistive element M1, the second magnetoresistive element M2, and the third magnetoresistive element M3 have a same magnetoresistive effect coefficient and/or have a same magnetic sensitivity direction.

In an embodiment, the first magnetoresistive element M1 extends from a first end of the first magnetoresistive element M1 to a second end of the first magnetoresistive element M1 in the opposite direction of the X direction; the second end of the first magnetoresistive element M1 is coupled to a first end of the second magnetoresistive element M2; the second magnetoresistive element M2 extends from the first end of the second magnetoresistive element M2 to a second end of the second magnetoresistive element M2 in the X direction; the second end of the second magnetoresistive element M2 is coupled to a first end of the third magnetoresistive element M3; the third magnetoresistive element M3 extends from the first end of the third magnetoresistive element M3 to a second end of the third magnetoresistive element M3 in the opposite direction of the X direction.

The second magnetoresistor 202 includes a fourth magnetoresistive element M4, a fifth magnetoresistive element M5, and a sixth magnetoresistive element M6 coupled in series. In an example, the fourth magnetoresistive element M4, the fifth magnetoresistive element M5, and the sixth magnetoresistive element M6 have a same magnetoresistive effect coefficient and/or have a same magnetic sensitivity direction.

In an embodiment, the fourth magnetoresistive element M4 extends from a first end of the fourth magnetoresistive element M4 to a second end of the fourth magnetoresistive element M4 in the opposite direction of the Y direction; the second end of the fourth magnetoresistive element M4 is coupled to a first end of the fifth magnetoresistive element M5; the fifth magnetoresistive element M5 extends from the first end of the fifth magnetoresistive element M5 to a second end of the fifth magnetoresistive element M5 in the Y direction; the second end of the fifth magnetoresistive element M5 is coupled to a first end of the sixth magnetoresistive element M6; the sixth magnetoresistive element M6 extends from the first end of the sixth magnetoresistive element M6 to a second end of the sixth magnetoresistive element M6 in the opposite direction of the Y direction.

The third magnetoresistor 203 includes a seventh magnetoresistive element M7, an eighth magnetoresistive element M8, and a ninth magnetoresistive element M9 coupled in series. In an example, the seventh magnetoresistive element M7, the eighth magnetoresistive element M8, and the ninth magnetoresistive element M9 have a same magnetoresistive effect coefficient and/or have a same magnetic sensitivity direction.

In an embodiment, the seventh magnetoresistive element M7 extends from a first end of the seventh magnetoresistive element M7 to a second end of the seventh magnetoresistive element M7 in the X direction; the second end of the seventh magnetoresistive element M7 is coupled to a first end of the eighth magnetoresistive element M8; the eighth magnetoresistive element M8 extends from the first end of the eighth magnetoresistive element M8 to a second end of the eighth magnetoresistive element M8 in the opposite direction of the X direction; the second end of the eighth magnetoresistive element M8 is coupled to a first end of the ninth magnetoresistive element M9; the ninth magnetoresistive element M9 extends from the first end of the ninth magnetoresistive element M9 to a second end of the ninth magnetoresistive element M9 in the X direction.

The fourth magnetoresistor 204 includes a tenth magnetoresistive element M10, an eleventh magnetoresistive element M11, and a twelfth magnetoresistive element M12 coupled in series. In an example, the tenth magnetoresistive element M10, the eleventh magnetoresistive element M11, and the twelfth magnetoresistive element M12 have a same magnetoresistive effect coefficient and/or have a same magnetic sensitivity direction.

In an embodiment, the tenth magnetoresistive element M10 extends from a first end of the tenth magnetoresistive element M10 to a second end of the tenth magnetoresistive element M10 in the opposite direction of the Y direction; the second end of the tenth magnetoresistive element M10 is coupled to a first end of the eleventh magnetoresistive element M11; the eleventh magnetoresistive element M11 extends from the first end of the eleventh magnetoresistive element M11 to a second end of the eleventh magnetoresistive element M11 in the Y direction; the second end of the eleventh magnetoresistive element M11 is coupled to a first end of the twelfth magnetoresistive element M12; the twelfth magnetoresistive element M12 extends from the first end of the twelfth magnetoresistive element M12 to a second end of the twelfth magnetoresistive element M12 in the opposite direction of the Y direction.

As shown in FIG. 11, the magnetic field sensing module provided by the present application includes a fifth magnetoresistor 205 and a sixth magnetoresistor 206.

The fifth magnetoresistor 205 and the sixth magnetoresistor 206 can each be composed of at least one magnetosensitive resistor (also known as a magnetoresistive element). In an embodiment, the fifth magnetoresistor 205 includes three magnetoresistive elements coupled in series, and the sixth magnetoresistor 206 includes three magnetoresistive elements coupled in series. The corresponding relationship between the current direction on the magnetoresistive elements and the current direction of the magnetoresistor has been described previously and will not be repeated here.

Based on this, the fifth magnetoresistor 205 forms a fifth current direction, and the sixth magnetoresistor 206 forms a sixth current direction; the fifth current direction is set at an angle to the sixth current direction. In an embodiment, the fifth current direction is perpendicular to the sixth current direction.

The fifth magnetoresistor 205 and the sixth magnetoresistor 206 are coupled in series.

The magnetic field sensing module provided by the present application includes a seventh magnetoresistor 207 and an eighth magnetoresistor 208.

The seventh magnetoresistor 207 and the eighth magnetoresistor 208 can each be composed of at least one magnetosensitive resistor (also known as a magnetoresistive element). In an embodiment, the seventh magnetoresistor 207 includes three magnetoresistive elements coupled in series, and the eighth magnetoresistor 208 includes three magnetoresistive elements coupled in series. The corresponding relationship between the current direction on the magnetoresistive elements and the current direction of the magnetoresistor has been described previously and will not be repeated here.

Based on this, the seventh magnetoresistor 207 forms a seventh current direction, and the eighth magnetoresistor 208 forms an eighth current direction; the seventh current direction is set at an angle to the eighth current direction. In an embodiment, the seventh current direction is perpendicular to the eighth current direction.

The seventh magnetoresistor 207 and the eighth magnetoresistor 208 are coupled in series.

The seventh magnetoresistor 207 and the eighth magnetoresistor 208 are coupled in parallel with the fifth magnetoresistor 205 and the sixth magnetoresistor 206; specifically, a magnetoresistive branch formed by the seventh magnetoresistor 207 and the eighth magnetoresistor 208 coupled in series is coupled in parallel with another magnetoresistive branch formed by the fifth magnetoresistor 205 and the sixth magnetoresistor 206 coupled in series.

A node for coupling one of the power supply voltage Vd and the reference ground Gnd is set at the fifth magnetoresistor 205 and the seventh magnetoresistor 207; another node for coupling the other one of the power supply voltage Vd and the reference ground Gnd is set at the sixth magnetoresistor 206 and the eighth magnetoresistor 208.

An output node is set between the fifth magnetoresistor 205 and the sixth magnetoresistor 206, such as a third output node V3; an output node is set between the seventh magnetoresistor 207 and the eighth magnetoresistor 208, such as a fourth output node V4. The fifth magnetoresistor 205 and the sixth magnetoresistor 206 coupled in series can form a half-bridge structure, and the seventh magnetoresistor 207 and the eighth magnetoresistor 208 coupled in series can form another half-bridge structure, thereby generating full-bridge signal outputs at the first output node V1 and the fourth output node V4.

Similarly to the previous description, the two magnetoresistive branches are mirror symmetrical and thus do not produce output for the signal magnetic field, only producing output due to the deflection of the magnetization direction caused by the excitation magnetic field, which can more accurately expand the output period of the magnetic field sensing module. Moreover, the two bridge arms correspond to each other, allowing the output curve to be corrected to symmetrically arrange around 0 mV, and cancel out the effects of external interference magnetic fields.

Such excitation magnetic fields can be formed by a magnetic field generation module. For example, a fifth magnetic field generation module 305 can be set at the fifth magnetoresistor 205 to generate a fifth excitation magnetic field Ba5 corresponding to the fifth magnetoresistor 205. For example, a sixth magnetic field generation module 306 can be set at the sixth magnetoresistor 206 to generate a sixth excitation magnetic field Ba6 corresponding to the sixth magnetoresistor 206. A seventh magnetic field generation module 307 can be set at the seventh magnetoresistor 207 to generate a seventh excitation magnetic field Ba7 corresponding to the seventh magnetoresistor 207. An eighth magnetic field generation module 308 can be set at the eighth magnetoresistor 208 to generate an eighth excitation magnetic field Ba8 corresponding to the eighth magnetoresistor 208.

The fifth magnetoresistor 205, the sixth magnetoresistor 206, the seventh magnetoresistor 207, and the eighth magnetoresistor 208 are applied with a signal magnetic field carrying direction information, forming a signal magnetization direction.

At the same time, the fifth magnetoresistor 205 is applied with the fifth excitation magnetic field Ba5, causing a signal magnetization direction at the fifth magnetoresistor 205 to deflect and form a fifth excitation magnetization direction; the sixth magnetoresistor 206 is applied with the sixth excitation magnetic field Ba6, causing the signal magnetization direction at the sixth magnetoresistor 206 to deflect and form a sixth excitation magnetization direction; the seventh magnetoresistor 207 is applied with the seventh excitation magnetic field Ba7, causing the signal magnetization direction at the seventh magnetoresistor 207 to deflect and form a seventh excitation magnetization direction; the eighth magnetoresistor 208 is applied with the eighth excitation magnetic field Ba8, causing the signal magnetization direction at the eighth magnetoresistor 208 to deflect and form the eighth excitation magnetization direction.

In an embodiment, a direction of the fifth excitation magnetic field Ba5 is opposite to a direction of the seventh excitation magnetic field Ba7.

In an embodiment, a direction of the sixth excitation magnetic field Ba6 is opposite to a direction of the eighth excitation magnetic field Ba8. In an embodiment, the configurations of the excitation magnetic field directions defined above are satisfied simultaneously.

The above construction forms another full-bridge structure distinct from a full-bridge structure formed by the first magnetoresistor 201, the second magnetoresistor 202, the third magnetoresistor 203, and the fourth magnetoresistor 204.

On the one hand, based on the above full-bridge structure, without switching states (where the first magnetoresistor 201 and the second magnetoresistor 202 correspond to the first state; the third magnetoresistor 203 and the fourth magnetoresistor 204 correspond to the second state), it is possible to achieve comparative output, which allows the sensing output of the magnetic field sensing module itself or the sensing direction information of the corresponding angle sensor to be matched to the first numerical interval, extending the output period and enhancing the richness of the magnetic field information content that can be obtained by the magnetic field sensing module.

Specifically, the third output node V3 and the fourth output node V4 can be coupled to form a difference signal, and the above extension and enrichment can be performed based on zero crossings of the difference signal.

Regarding a relationship between the directions of the excitation magnetic fields: in an embodiment, a direction of the fifth excitation magnetic field Ba5 is opposite to a direction of the seventh excitation magnetic field Ba7; a direction of the sixth excitation magnetic field Ba6 is opposite to a direction of the eighth excitation magnetic field Ba8. In an example, a direction of the fifth excitation magnetic field Ba5 points in the Y direction, a direction of the seventh excitation magnetic field Ba7 points in the opposite direction of the Y direction; a direction of the sixth excitation magnetic field Ba6 points in the Y direction, and a direction of the eighth excitation magnetic field Ba8 points in the opposite direction of the Y direction.

In an embodiment, the direction of the fifth excitation magnetic field Ba5 and the direction of the sixth excitation magnetic field Ba6 are the same.

In an embodiment, the direction of the seventh excitation magnetic field Ba7 and the direction of the eighth excitation magnetic field Ba8 are the same.

Regarding the relationship between current directions: in an embodiment, the fifth current direction is perpendicular to the sixth current direction.

In an embodiment, the seventh current direction is perpendicular to the eighth current direction.

Regarding a relationship between the direction of the excitation magnetic field and the current direction: in an embodiment, a direction of the fifth excitation magnetic field Ba5 is perpendicular to the fifth current direction; a direction of the sixth excitation magnetic field Ba6 is parallel to the sixth current direction.

In an embodiment, a direction of the seventh excitation magnetic field Ba7 is perpendicular to the seventh current direction; a direction of the eighth excitation magnetic field Ba8 is parallel to the eighth current direction.

The various technical solutions, embodiments, and examples provided by the present application can be combined to form new technical solutions.

For example, the magnetic field sensing module can simultaneously include the first magnetoresistor 201 to the fourth magnetoresistor 204, as well as the fifth magnetoresistor 205 to the eighth magnetoresistor 208.

The first magnetoresistor 201 and the second magnetoresistor 202 are configured to form a first output node signal, specifically generated at the first output node V1; the third magnetoresistor 203 and the fourth magnetoresistor 204 are configured to form a second output node signal, specifically generated at the second output node V2. The first magnetoresistor 201 and the second magnetoresistor 202 coupled in series can form a half-bridge structure, and the third magnetoresistor 203 and the fourth magnetoresistor 204 coupled in series can form another half-bridge structure, thereby generating a full-bridge signal output at the first output node V1 and the second output node V2.

The fifth magnetoresistor 205 and the sixth magnetoresistor 206 are configured to form a third output node signal, specifically generated at the third output node V3; the seventh magnetoresistor 207 and the eighth magnetoresistor 208 are configured to form a fourth output node signal, specifically generated at the fourth output node V4. The fifth magnetoresistor 205 and the sixth magnetoresistor 206 coupled in series can form a half-bridge structure, and the seventh magnetoresistor 207 and the eighth magnetoresistor 208 coupled in series can form another half-bridge structure, thereby generating another full-bridge signal output at the third output node V3 and the fourth output node V4.

On the one hand, the first magnetoresistor 201 and the second magnetoresistor 202 coupled in series form a first magnetoresistive branch, the third magnetoresistor 203 and the fourth magnetoresistor 204 coupled in series form a second magnetoresistive branch, the fifth magnetoresistor 205 and the sixth magnetoresistor 206 coupled in series form a third magnetoresistive branch, and the seventh magnetoresistor 207 and the eighth magnetoresistor 208 coupled in series form a fourth magnetoresistive branch. The four magnetoresistive branches respectively form four bridge arms of the magnetic field sensing module.

On the other hand, the first magnetoresistor 201 and the second magnetoresistor 202 coupled in parallel with the third magnetoresistor 203 and the fourth magnetoresistor 204 form a first full-bridge structure, and the fifth magnetoresistor 205 and the sixth magnetoresistor 206 coupled in parallel with the seventh magnetoresistor 207 and the eighth magnetoresistor 208 form a second full-bridge structure. In this way, the magnetic field sensing module is configured as a dual full-bridge structure, balancing the advantages of both the dual half-bridge structure and the full-bridge structure mentioned above.

Specifically, compared to the dual half-bridge structure, an output of the first magnetoresistor 201 and an output of the second magnetoresistor 202 correspond to an output of one of the half-bridges in the first state; an output of the third magnetoresistor 203 and an output of the fourth magnetoresistor 204 correspond to an output of one of the half-bridges in the second state; an output of the fifth magnetoresistor 205 and the sixth magnetoresistor 206 correspond to an output of another of the half-bridges in the second state; an output of the seventh magnetoresistor 207 and an output of the eighth magnetoresistor 208 correspond to an output of another of the half-bridges in the first state.

The first output node signal and the second output node signal form a corresponding first difference signal; the fourth output node signal and the third output node signal form a corresponding second difference signal. The difference signals mentioned above can be obtained through separate subtraction operations or by forming a connection based on circuit coupling relationships between two output node signals. Preferably, the difference signals can be directly formed by coupling the nodes; for example, the first output node V1 and the second output node V2 are coupled to form the first difference signal output; and the third output node V3 and the fourth output node V4 are coupled to form the second difference signal output.

The first difference signal presents a first difference output curve DO1 as shown in FIG. 12; the second difference signal presents a second difference output curve DO2 as shown in FIG. 12. Both of the two difference signals have a 360-degree output period; in an embodiment, both can have a fixed phase difference.

In an embodiment, the two difference output curves can compensate each other to ensure stability within the 0-degree to 360-degree interval. In an embodiment, the phase difference between the first difference output curve DO1 and the second difference output curve DO2 is 90 degrees; thus, maximizing stability throughout the entire output interval range.

The first difference signal and the second difference signal are configured to match the sensing output of the magnetic field sensing module itself, or sensing direction information of the angle sensor corresponding to the magnetic field sensing module to the first numerical interval. In an embodiment, the range of the first numerical interval is greater than the range of the second numerical interval supported by the sensing modules or angle sensors in the prior art. In an embodiment, the first numerical interval includes the numerical interval from 0 degrees to 360 degrees.

In an embodiment, the first difference signal and the second difference signal can achieve the matching of the first numerical interval through their own zero crossings or the distribution relationship between the two sets of zero crossings; specifically, the expansion from a 180-degree output period to a 360-degree output period can be realized.

Regarding a relationship between the directions of the excitation magnetic fields: in an embodiment, a direction of the first excitation magnetic field Ba1 and a direction of the second excitation magnetic field Ba2 are the same.

In an embodiment, a direction of the third excitation magnetic field Ba3 and a direction of the fourth excitation magnetic field Ba4 are the same.

Regarding a relationship between current directions: in an embodiment, the fifth current direction is parallel to the first current direction; the third current direction is parallel to the first current direction; the seventh current direction is parallel to the first current direction.

In an embodiment, the sixth current direction is parallel to the second current direction; the fourth current direction is parallel to the second current direction; the eighth current direction is parallel to the second current direction.

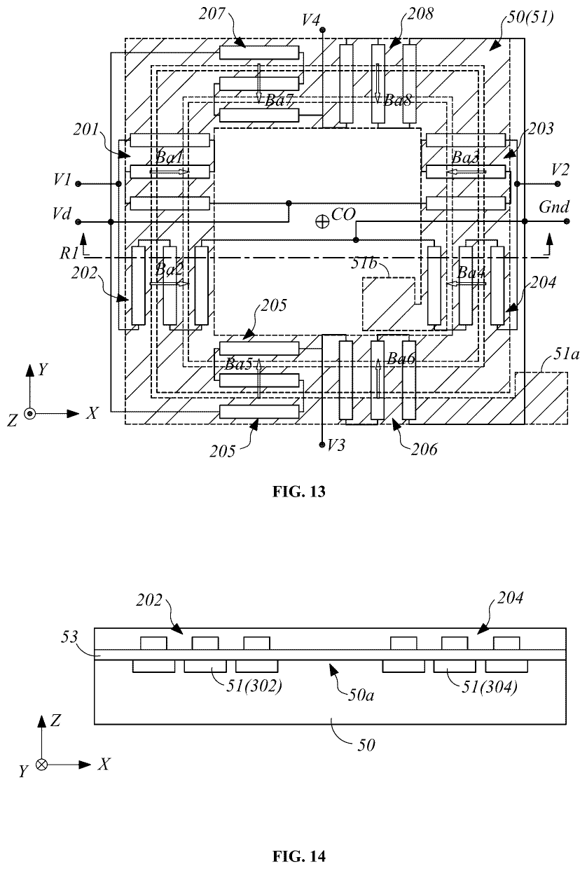

As shown in FIG. 13, in conjunction with FIG. 11 and FIG. 16, the magnetic field sensing module provided by the present application can be arranged in an enclosing manner when it simultaneously includes the first magnetoresistor 201, the second magnetoresistor 202, the third magnetoresistor 203, the fourth magnetoresistor 204, the fifth magnetoresistor 205, the sixth magnetoresistor 206, the seventh magnetoresistor 207 and the eighth magnetoresistor 208.

A geometric center CO of the magnetic field sensing module is defined, which can be a virtual center defined for convenience of description.

The magnetic field sensing module comprises a first magnetoresistor 201 and a second magnetoresistor 202 arranged on one side of the geometric center CO in an opposite direction of a first direction (e.g., the opposite direction of the X direction); the first magnetoresistor 201 and the second magnetoresistor 202 are coupled in series; the second magnetoresistor 202 and the first magnetoresistor 201 are arranged at intervals in a second direction (e.g., the Y direction or its opposite direction). In an embodiment, the first magnetoresistor 201 is disposed on one side of the second direction (e.g., the Y direction) of a first axis extending along the first direction (e.g., the X direction or its opposite direction) and passing through the geometric center CO; the second magnetoresistor 202 is disposed on another side of an opposite direction of the second direction (e.g., the opposite direction of the Y direction) of the first axis.

The magnetic field sensing module comprises a third magnetoresistor 203 and a fourth magnetoresistor 204 arranged on one side of the geometric center CO in the first direction (e.g., the X direction); the third magnetoresistor 203 and the fourth magnetoresistor 204 are coupled in series; the fourth magnetoresistor 204 and the third magnetoresistor 203 are arranged at intervals in the second direction (e.g., the Y direction or its opposite direction). In an embodiment, the third magnetoresistor 203 is disposed on one side of the second direction (e.g., the Y direction) of the first axis; the second magnetoresistor 202 is disposed on another side of the opposite direction of the second direction (e.g., the opposite direction of the Y direction) of the first axis.

The magnetic field sensing module comprises a fifth magnetoresistor 205 and a sixth magnetoresistor 206 arranged on one side of the geometric center CO in an opposite direction of the second direction (e.g., the opposite direction of the Y direction); the fifth magnetoresistor 205 and the sixth magnetoresistor 206 are coupled in series; the fifth magnetoresistor 205 and the sixth magnetoresistor 206 are arranged at intervals in the first direction (e.g., the X direction or its opposite direction). In an embodiment, the fifth magnetoresistor 205 is disposed on one side of the first direction (e.g., the opposite direction of the X direction) of a second axis extending along the second direction (e.g., the Y direction or its opposite direction) and passing through the geometric center CO; the sixth magnetoresistor 206 is disposed on another side of the opposite direction of the first direction (e.g., the X direction) of the second axis.

The magnetic field sensing module comprises a seventh magnetoresistor 207 and an eighth magnetoresistor 208 arranged on one side of the geometric center CO in the second direction (e.g., the Y direction); the seventh magnetoresistor 207 and the eighth magnetoresistor 208 are coupled in series; the seventh magnetoresistor 207 and the eighth magnetoresistor 208 are arranged at intervals in the first direction (e.g., the X direction or its opposite direction). In an embodiment, the seventh magnetoresistor 207 is disposed on one side of the first direction (e.g., the opposite direction of the X direction) of the second axis; the eighth magnetoresistor 208 is disposed on another side of the opposite direction of the first direction (e.g., the X direction) of the second axis.

In an embodiment, the first direction is perpendicular to the second direction.

In an embodiment, magnetoresistive elements in at least one of the first magnetoresistor 201, the third magnetoresistor 203, the fifth magnetoresistor 205, and the seventh magnetoresistor 207 extend along the first direction (e.g., the X direction or its opposite direction).

In an embodiment, magnetoresistive elements in at least one of the second magnetoresistor 202, the fourth magnetoresistor 204, the sixth magnetoresistor 206, and the eighth magnetoresistor 208 extend along the second direction (e.g., the Y direction or its opposite direction).

In an embodiment, with the geometric center CO, the first magnetoresistor 201, the second magnetoresistor 202, the fifth magnetoresistor 205, the sixth magnetoresistor 206, the fourth magnetoresistor 204, the third magnetoresistor 203, the eighth magnetoresistor 208, and the seventh magnetoresistor 207 are arranged in a counterclockwise direction in sequence.

In an embodiment, the first magnetoresistor 201, the second magnetoresistor 202, the fifth magnetoresistor 205, the sixth magnetoresistor 206, the fourth magnetoresistor 204, the third magnetoresistor 203, the eighth magnetoresistor 208, and the seventh magnetoresistor 207 are arranged to form a central space. In an example, the central space can be configured to set at least one of the above-mentioned output node, the power supply node of the magnetoresistors or the power supply node of the magnetoresistive element of the magnetoresistors (i.e., nodes for connecting the supply voltage Vd or the reference ground Gnd), or a second conductor end 51b described below, among other structures.

The technical solutions, embodiments, or examples provided by the present application can be combined to form configurations that balance the corresponding technical effects.

As shown in FIG. 13, in conjunction with FIG. 16, the present application provides a magnetic field sensor that includes any of the magnetic field sensing modules provided by the above-mentioned technical solutions, embodiments, or examples.

The magnetic field sensor further includes an excitation coil for generating an excitation magnetic field at the magnetic field sensing module. In an embodiment, the magnetic field generation module described above can be replaced with the excitation coil.

A magnetoresistive element in the magnetic field sensing module is arranged along a first direction (e.g., an X direction or an opposite direction of the X direction) or a second direction (e.g., a Y direction or an opposite direction of the Y direction), The excitation coil is arranged on at least one side (e.g., a Z direction side or an opposite direction side of the Z direction) of the magnetic field sensing module in a third direction (e.g., the Z direction or its opposite direction).

The third direction is perpendicular to both the first direction and the second direction.

The excitation coil can be configured as a single-layer coil or a multi-layer coil. The number of conductor sections in the excitation coil can match the number of magnetoresistive elements in the corresponding magnetoresistors; several conductor sections can be arranged at intervals in a direction near and away from a geometric center CO; the conductor sections arranged at intervals in the direction are set parallel to each other.

As shown in FIG. 14, in conjunction with FIG. 13 and FIG. 16, the excitation coil can be set on one side of the magnetic field sensing module in an opposite direction of the third direction (e.g., the opposite direction of the Z direction); the excitation coil can be configured as a single layer.

The magnetic field sensing module (illustrated in FIG. 14 with a second magnetoresistor 202 and a fourth magnetoresistor 204) is formed on a first side 50a of a substrate 50. The excitation coil comprises a first coil 51 arranged on a side of the magnetic field sensing module close to the substrate 50. Thus, the excitation coil can generate an excitation magnetic field at the magnetic field sensing module that is parallel to the first side 50a or an extension surface of the magnetic field sensing module; specifically, the excitation coil can generate a magnetic field component parallel to an X-Y plane at the magnetic field sensing module.

The first coil 51 corresponds to a second magnetic field generation module 302 for the second magnetoresistor 202; the first coil 51 corresponds to a fourth magnetic field generation module 304 for the fourth magnetoresistor 204. The first coil 51 forms corresponding magnetic field generation modules for other magnetoresistors, which will not be further detailed here.

The number of conductor sections in the first coil 51 matches the number of magnetoresistive elements in the corresponding magnetoresistors. For example, when the second magnetoresistor 202 includes three magnetoresistive elements, the first coil 51 forming the second magnetic field generation module 302 has three groups of conductor sections. The number of conductor sections in the first coil 51 can also match the number of magnetoresistive elements in other magnetoresistors, which will not be further detailed here.

In an embodiment, several magnetoresistive elements in a same magnetoresistor are parallel to each other, and the corresponding conductor sections in a same magnetoresistor are also parallel to each other; for the corresponding conductor section and magnetoresistive element, an extension direction of a conductor section is parallel or perpendicular to an extension direction of a magnetoresistive element (e.g., parallel to an extension direction of the magnetoresistive elements of the second magnetoresistor 202 and their corresponding conductor sections, or perpendicular to an extension direction of the magnetoresistive elements of a first magnetoresistor 201 and their corresponding conductor sections).

If an extension direction of a conductor section is parallel to an extension direction of a magnetoresistive element, projection of the conductor section on one side of the magnetoresistive element covers the corresponding magnetoresistive element, In an embodiment, the conductor section are located directly below the magnetoresistive element (in the opposite direction of the Z direction), and the area of the corresponding side (e.g., a bottom side) of the magnetoresistive element is smaller than the area of the corresponding side (e.g., a top side) of the conductor section.

If an extension direction of a conductor section is perpendicular to an extension direction of a magnetoresistive element, projection of the conductor section on one side of the magnetoresistive element at least covers most of the corresponding magnetoresistive element. Thus, the excitation magnetic field has a stronger intensity.

In an embodiment, an isolation layer is arranged between the first coil and the magnetic field sensing module. Thus, the isolation layer can shield unwanted electromagnetic interference.

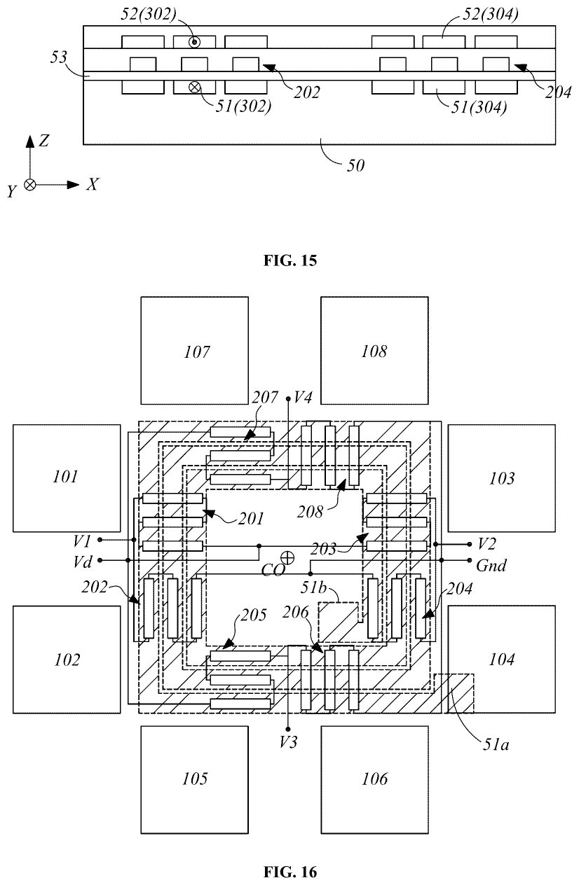

As shown in FIG. 15, in conjunction with FIG. 13 and FIG. 16, the excitation coil can be configured as a double layer and can be set on both sides of the magnetic field sensing module in the third direction or on a same side of the third direction.

In an embodiment, the excitation coil comprises a first coil 51 and a second coil 52 arranged on both sides of the magnetic field sensing module in the third direction.

The magnetic field sensing module (illustrated in FIG. 15 with the second magnetoresistor 202 and the fourth magnetoresistor 204) is formed on the first side 50a of the substrate 50. The first coil 51 is disposed on the side of the magnetic field sensing module near the substrate 50; the second coil 52 is disposed on a side of the magnetic field sensing module away from the substrate 50. Thus, the excitation coil can generate an excitation magnetic field at the magnetic field sensing module that is parallel to the first side 50a or an extension surface of the magnetic field sensing module; specifically, the excitation coil can generate a magnetic field component parallel to an X-Y plane at the magnetic field sensing module.

For example, the first coil 51 is disposed on a side of the magnetic field sensing module in the opposite direction of the third direction (e.g., the opposite direction of the Z direction), and the second coil 52 is disposed on a side of the magnetic field sensing module in the third direction (e.g., the Z direction).

The first coil 51 and the second coil 52 correspond to the conductor sections of the second magnetoresistor 202 to form the second magnetic field generation module 302; the first coil 51 and the second coil 52 correspond to the conductor sections of the fourth magnetoresistor 204 to form the fourth magnetic field generation module 304.

The directions of excitation magnetic fields generated by the first coil 51 and the second coil 52 corresponding to a same position of the magnetic field sensing module are same to form the superposition of the excitation magnetic field intensity.

The current directions at the conductor sections of the first coil 51 and the second coil 52 with a same projection position on a side of the magnetic field sensing module are opposite to form the superposition of the excitation magnetic field intensity.

For example, the current in the conductor section of the first coil 51 corresponding to the second magnetoresistor 202 flows inward perpendicular to the page and along the second direction (e.g., along the Y direction), generating an excitation magnetic field (e.g., a second excitation magnetic field Ba2 or its part) at the second magnetoresistor 202 pointing in the first direction (e.g., the X direction). The current in the conductor section of the second coil 52 corresponding to the second magnetoresistor 202 flows outward perpendicular to the page and along an opposite direction of the second direction (e.g., along the opposite direction of the Y direction), generating an excitation magnetic field (e.g., the second excitation magnetic field Ba2 or its part) at the second magnetoresistor 202 pointing in the first direction (e.g., the X direction) as well. Thus, the excitation magnetic fields can be superimposed.

The configuration of the currents in the conductor sections of other magnetic field sensing modules and their corresponding conductor sections will not be further detailed here.

In an embodiment shown in FIG. 13 or FIG. 16, where the coils are arranged in a spiral manner close to the magnetic field sensing module, for example, the first coil 51 comprises a first conductor end 51a and a second conductor end 51b. The current in the first coil 51 can flow from the first conductor end 51a to the second conductor end 51b, forming a clockwise inward (defined as “inward” towards the geometric center CO) flow direction. At this time, from the perspective of FIG. 13 and FIG. 16, the current in the second coil 52 can form a counterclockwise inward or counterclockwise outward flow direction to form the superposition of the excitation magnetic field, enhancing the sensitivity of a magnetic sensor.

In an embodiment, the second coil 52 has a same structure as the first coil 51, but the current in the first coil 51 flows from the first conductor end 51a of the first coil 51 to the second conductor end 51b of the first coil 51, while the current in the second coil 52 flows from the second conductor end of the second coil 52 to the first conductor end of the second coil 52.

In an embodiment, the excitation coil includes a first coil 51. The first coil 51 includes a first conductor end 51a arranged on a side of the magnetic field sensing module away from the geometric center CO. The first coil 51 extends from the first conductor end 51a around the geometric center CO along the first direction (e.g., the X direction or its opposite direction) or the second direction (e.g., the Y direction or its opposite direction) and extends close to the geometric center CO to form a second conductor end 51b.

In an embodiment, projection of a conductor section of the first coil 51 between the first conductor end 51a and the second conductor end 51b on the magnetic field sensing module at least covers all the magnetoresistive elements with a same extension direction as the conductor section.

For example, at the second magnetoresistor 202 and the fourth magnetoresistor 204, the magnetoresistive elements and the corresponding conductor sections extend along the second direction (e.g., the Y direction or its opposite direction); at this time, projection of the conductor sections on the corresponding magnetoresistors (especially the projection along the third direction) at least covers the corresponding magnetoresistive elements.

For example, at the fifth magnetoresistor 205 and the seventh magnetoresistor 207, the magnetoresistive elements and the corresponding conductor sections extend along the first direction (e.g., the X direction or its opposite direction); at this time, projection of the conductor sections on the corresponding magnetoresistors (especially the projection along the third direction) at least covers the corresponding magnetoresistive elements.

As shown in FIG. 16, a magnetic sensor further comprises an angle sensor that cooperates with the magnetic field sensing module. The angle sensor is at least configured to provide sensing direction information for a signal magnetic field. In other embodiments, the angle sensor can provide other motion information or other state information of the object to be measured.

The angle sensor is arranged on a side of the magnetoresistors away from the geometric center CO. The angle sensor is arranged around the magnetoresistors. When the angle sensor includes multiple components, the multiple components are arranged at intervals and surround the magnetoresistors and arranged on an outer side (defined as “outer” being away from the geometric center CO) of the magnetoresistors.

In an embodiment, the angle sensor is composed of at least one magnetoresistive unit. The magnetoresistive unit is defined as a resistive element sensitive to magnetic fields and having magnetoresistive effects; the magnetoresistive unit can have a same or similar internal structure as the magnetic resistors and magnetoresistive elements.

In an embodiment, the angle sensor includes a first magnetoresistive unit 101 and a second magnetoresistive unit 102, corresponding to the first magnetoresistor 201 and the second magnetoresistor 202, respectively. The first magnetoresistive unit 101 is disposed near the first magnetoresistor 201; the first magnetoresistive unit 101 is set on a side of the first magnetoresistor 201 away from the geometric center CO. The second magnetoresistive unit 102 is disposed near the second magnetoresistor 202; the second magnetoresistive unit 102 is set on a side of the second magnetoresistor 202 away from the geometric center CO. In an example, an internal structure of the angle sensor is similar to a half-bridge structure.

In an embodiment, the angle sensor includes a third magnetoresistive unit 103 and a fourth magnetoresistive unit 104, corresponding to a third magnetoresistor 203 and a fourth magnetoresistor 204, respectively. The positional relationships between the magnetoresistive units and the magnetoresistors can refer to the above descriptions and will not be further detailed here. When the magnetic field sensing module is composed of the first magnetoresistor 201, the second magnetoresistor 202, the third magnetoresistor 203, and the fourth magnetoresistor 204 forming a full-bridge structure, the angle sensor includes at least the first magnetoresistive unit 101, the second magnetoresistive unit 102, the third magnetoresistive unit 103, and the fourth magnetoresistive unit 104. In an example, an internal structure of the angle sensor also forms a full-bridge structure.

In an embodiment, the angle sensor includes a seventh magnetoresistive unit 107 and an eighth magnetoresistive unit 108, corresponding to a seventh magnetoresistor 207 and an eighth magnetoresistor 208, respectively. The positional relationships between the magnetoresistive units and the magnetoresistors can refer to the above descriptions and will not be further detailed here. When the magnetic field sensing module is composed of the first magnetoresistor 201, the second magnetoresistor 202, the seventh magnetoresistor 207, and the eighth magnetoresistor 208 forming a dual half-bridge structure, the angle sensor includes at least the first magnetoresistive unit 101, the second magnetoresistive unit 102, the seventh magnetoresistive unit 107, and the eighth magnetoresistive unit 108. In an example, an internal structure of the angle sensor also forms a dual half-bridge structure.

In an embodiment, the angle sensor includes a fifth magnetoresistive unit 105 and a sixth magnetoresistive unit 106, corresponding to a fifth magnetoresistor 205 and a sixth magnetoresistor 206, respectively. The positional relationships between the magnetoresistive units and the magnetoresistors can refer to the above descriptions and will not be further detailed here. When the magnetic field sensing module is composed of the first magnetoresistor 201, the second magnetoresistor 202, the third magnetoresistor 203, the fourth magnetoresistor 204, the fifth magnetoresistor 205, the sixth magnetoresistor 206, the seventh magnetoresistor 207, and the eighth magnetoresistor 208 forming a dual full-bridge structure, the angle sensor includes at least the first magnetoresistive unit 101, the second magnetoresistive unit 102, the third magnetoresistive unit 103, the fourth magnetoresistive unit 104, the fifth magnetoresistive unit 105, the sixth magnetoresistive unit 106, the seventh magnetoresistive unit 107, and the eighth magnetoresistive unit 108. In an example, an internal structure of the angle sensor also forms a dual full-bridge structure.

In an embodiment, several magnetoresistive units or other sensing units in the angle sensor are arranged symmetrical with respect to the geometric center CO.

The technical solutions, embodiments, or examples provided by the present application can be combined to form configurations that balance the corresponding technical effects.

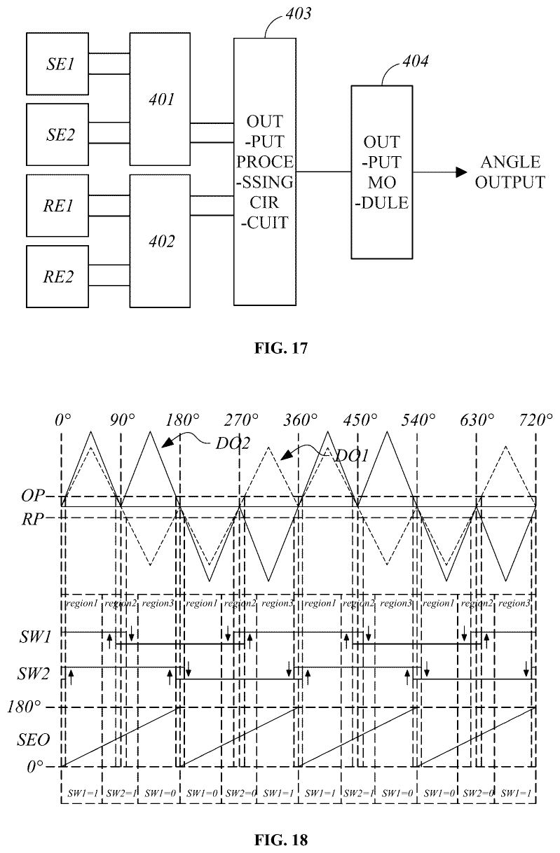

As shown in FIG. 17, in conjunction with FIG. 16, the present application provides a magnetic sensor that comprises any magnetic field sensing module provided by the above-mentioned technical solutions, embodiments, or examples.

The magnetic field sensing module is configured to form a difference signal containing several zero crossings.

The magnetic sensor further comprises an angle sensor. The sensing direction information obtained by the angle sensor for the signal magnetic field is distributed in a second numerical interval. Actual direction information of the signal magnetic field is distributed in a first numerical interval; a range of the first numerical interval is greater than a range of the second numerical interval. In an embodiment, the first numerical interval is from 0 degrees to 360 degrees, and the second numerical interval is from 0 degrees to 180 degrees.

The magnetic sensor comprises a signal processing circuit; the signal processing circuit is coupled to an output node of the magnetic field sensing module. The signal processing circuit is configured at least to generate a square wave signal based on the difference signal.

The magnetic sensor comprises an output processing circuit 403; the output processing circuit 403 is coupled to the signal processing circuit. The output processing circuit 403 is configured to match the sensing direction information to the first numerical interval based on the square wave signal so that the sensing direction information is consistent with the actual direction information.

For example, based on the limitation of an output period of the angle sensor or the magnetic field sensing module, even for an object to be measured whose rotation angle changes within a range of 0 degrees to 360 degrees, the output of the angle sensor or the magnetic field sensing module in prior art can only be generated within a range of 0 degrees to 180 degrees. Based on the magnetic sensor provided by the present application, the output period of the angle sensor or the magnetic field sensing module can be expanded and the magnetic field signal content can be enriched on the basis of the original architecture, generating an output within a range of 0 degrees to 360 degrees, consistent with the actual rotation of the object to be measured. It should be understood that the above is only a description of one application scenario of the present application.

In an embodiment, the angle sensor forms a first sensing branch SE1 and a second sensing branch SE2. They can be configured as a full-bridge structure or a half-bridge structure.

The magnetic field sensing module can form a corresponding first sensing branch RE1 and a second sensing branch RE2.

Refer to the previous text, when the magnetic field sensing module is configured as a single half-bridge structure (e.g., including the first magnetoresistor 201 and the second magnetoresistor 202), the first sensing branch RE1 represents a circuit structure providing the single half-bridge output in a first state, and the second sensing branch RE2 represents a circuit structure providing the single half-bridge output in a second state.

When the magnetic field sensing module is configured as a dual half-bridge structure (e.g., including the first magnetoresistor 201, the second magnetoresistor 202, the seventh magnetoresistor 207, and the eighth magnetoresistor 208), the first sensing branch RE1 represents the circuit structure providing the dual half-bridge output in the first state, and the second sensing branch RE2 represents the circuit structure providing the dual half-bridge output in the second state.

When the magnetic field sensing module is configured as a full-bridge structure (e.g., including the first magnetoresistor 201, the second magnetoresistor 202, the third magnetoresistor 203, and the fourth magnetoresistor 204), the first sensing branch RE1 represents one half-bridge structure, and the second sensing branch RE2 represents another half-bridge structure.

When the magnetic field sensing module is configured as a dual full-bridge structure (e.g., including the first magnetoresistor 201, the second magnetoresistor 202, the third magnetoresistor 203, the fourth magnetoresistor 204, the fifth magnetoresistor 205, the sixth magnetoresistor 206, the seventh magnetoresistor 207, and the eighth magnetoresistor 208), the first sensing branch RE1 represents one full-bridge structure, and the second sensing branch RE2 represents another full-bridge structure.

Below, the principles and effects will be described by taking the configuration of the magnetic field sensing module as a dual half-bridge structure or a dual full-bridge structure as examples.

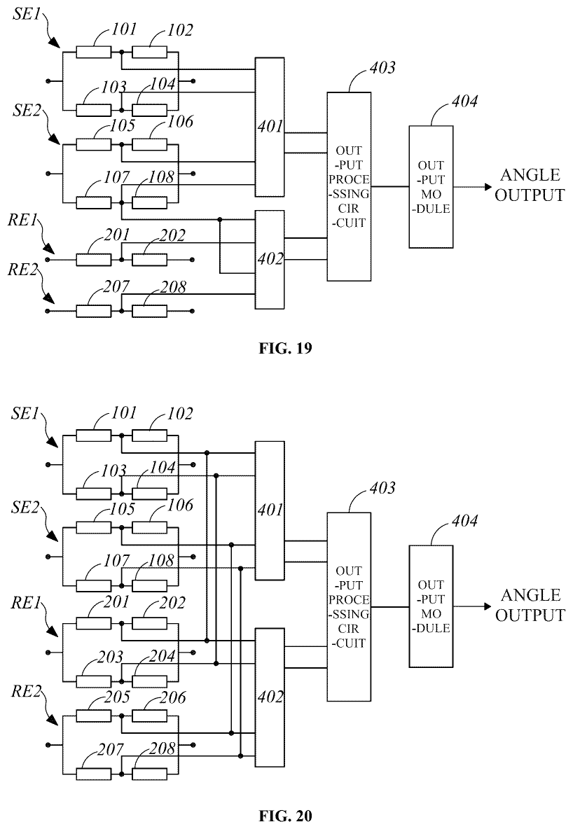

As shown in FIG. 11, FIG. 12, FIG. 13, FIG. 16, FIG. 17, FIG. 18, FIG. 19 and FIG. 20, the magnetic field sensing module comprises a seventh magnetoresistor 207 and an eighth magnetoresistor 208.

A first output node V1 is set between the first magnetoresistor 201 and the second magnetoresistor 202. The first output node V1 is coupled to a signal processing circuit (e.g., a second signal processing circuit 402). The first output node V1 is configured to form a first difference signal, which presents a first difference output curve DO1.

A fourth output node V4 is set between the seventh magnetoresistor 207 and the eighth magnetoresistor 208. The fourth output node V4 is coupled to a signal processing circuit (e.g., a second signal processing circuit 402). The fourth output node V4 is configured to form a second difference signal, which presents a second difference output curve DO2.

In an embodiment, a phase difference is configured between the first difference signal and the second difference signal. In an example, the phase difference is 90 degrees. In an example, a period of the first difference signal is 360 degrees, and a period of the second difference signal is 360 degrees.

The signal processing circuit is configured to form a first square wave signal SW1 based on the high and low levels of the first difference signal relative to a preset voltage threshold. In an example, the preset voltage threshold is set with a high threshold OP (which can be greater than 0) and a low threshold RP (which can be less than 0); when a level of the first difference signal is higher than the high threshold OP, a high level part of the first square wave signal SW1 is generated accordingly; when a level of the first difference signal is lower than the low threshold RP, a low level part of the first square wave signal SW1 is generated. In an embodiment, the high threshold OP and the low threshold RP can be equal and set to 0.

The signal processing circuit is configured to form a second square wave signal SW2 based on the high and low levels of the second difference signal relative to the preset voltage threshold. In an example, the preset voltage threshold is set with a high threshold OP (which can be greater than 0) and a low threshold RP (which can be less than 0); when a level of the second difference signal is higher than the high threshold OP, a high level part of the second square wave signal SW2 is generated accordingly; when a level of the second difference signal is lower than the low threshold RP, a low level part of the second square wave signal SW2 is generated.

In an embodiment, a same preset voltage threshold can be set for the first difference signal and the second difference signal.

In an embodiment, the output processing circuit 403 is configured to output the sensing direction information when a sensed angle value falls into a first angle range region1 of the second numerical interval and the first square wave signal SW1 is at a high level (SW1=1). At this time, the output generated by the angle sensor does not need to be matched to the numerical interval, and the sensing direction information of the angle sensor is consistent with the actual direction information, so the sensing direction information is directly output.

In an embodiment, the output processing circuit 403 is configured to add a sensed angle value to a length of the second numerical interval and output the sum value when the sensed angle value falls into a first angle range region1 of the second numerical interval and the first square wave signal SW1 is at a low level (SW1=0). At this time, the actual angle value carried by the actual direction information exceeds the output period of the angle sensor (e.g., falling into the range of 180 degrees to 240 degrees), and the sensing direction information of the angle sensor is inconsistent with the actual direction information. Therefore, the sensed angle value is compensated and then output; the compensation amount is the length of the second numerical interval. In an example, the length of the second numerical interval is 180 degrees.

In an embodiment, the output processing circuit 403 is configured to output the sensing direction information when a sensed angle value falls into a second angle range region2 of the second numerical interval and the second square wave signal SW2 is at a high level (SW2=1). At this time, the output generated by the angle sensor does not need to be matched to the numerical interval, and the sensing direction information of the angle sensor is consistent with the actual direction information, so the sensing direction information is directly output.

In an embodiment, the output processing circuit 403 is configured to add a sensed angle value to a length of the second numerical interval and output the sum value when the sensed angle value falls into a second angle range region2 of the second numerical interval and the second square wave signal SW2 is at a low level (SW2=0). At this time, the actual angle value carried by the actual direction information exceeds the output period of the angle sensor (e.g., falling into the range of 230 degrees to 300 degrees), and the sensing direction information of the angle sensor is inconsistent with the actual direction information. Therefore, the sensed angle value is compensated and then output; the compensation amount is the length of the second numerical interval. In an example, the length of the second numerical interval is 180 degrees.

In an embodiment, the output processing circuit 403 is configured to add a sensed angle value to a length of the second numerical interval and then output the sum value when the sensed angle value falls into a third angle range region3 of the second numerical interval and the first square wave signal SW1 is at a high level (SW1=1). At this time, the actual angle value carried by the actual direction information exceeds the output period of the angle sensor (e.g., falling into the range of 300 degrees to 360 degrees), and the sensing direction information of the angle sensor is inconsistent with the actual direction information. Therefore, the sensed angle value is compensated and then output; the compensation amount is the length of the second numerical interval. In an example, the length of the second numerical interval is 180 degrees.

In an embodiment, the output processing circuit 403 is configured to output the sensing direction information when a sensed angle value falls into a third angle range region3 of the second numerical interval and the first square wave signal SW1 is at a low level (SW1=0). At this time, the output generated by the angle sensor does not need to be matched to the numerical interval, and the sensing direction information of the angle sensor is consistent with the actual direction information, so the sensing direction information is directly output.

The sensing direction information carries the sensed angle value.

In an embodiment, the output processing circuit 403 is configured as a combination of the above two or more embodiments,

In an embodiment, the first numerical interval is from 0 degrees to 360 degrees, the second numerical interval is from 0 degrees to 180 degrees, and the phase difference between the first difference signal and the second difference signal is 90 degrees.

For a dual half-bridge structure shown in FIG. 19, the first difference signal is a difference between the output of the first output node V1 in the first state and the output in the second state; the second difference signal is a difference between the output of the second output node V2 in the first state and the output in the second state.

For the dual full-bridge structure shown in FIG. 20, the first difference signal is a difference between the output of the first output node V1 and the output of the second output node V2; the second difference signal is a difference between the output of the third output node V3 and the output of the fourth output node V4.

As shown in FIG. 19 and FIG. 20, a first magnetoresistor unit 101, a second magnetoresistor unit 102, a third magnetoresistor unit 103, and a fourth magnetoresistor unit 104 form a first sensing branch SE1. The first sensing branch SE1 is configured as a full-bridge structure.

The first magnetoresistor unit 101 is coupled in series with the second magnetoresistor unit 102, and an intermediate node between the first magnetoresistor unit 101 and the second magnetoresistor unit 102 is used as an output node, coupled to the signal processing circuit (specifically, coupled to a first signal processing circuit 401).

The third magnetoresistor unit 103 is coupled in series with the fourth magnetoresistor unit 104, and an intermediate node between the third magnetoresistor unit 103 and the fourth magnetoresistor unit 104 is used as an output node, coupled to the signal processing circuit (specifically, coupled to the first signal processing circuit 401).

A fifth magnetoresistor unit 105, a sixth magnetoresistor unit 106, a seventh magnetoresistor unit 107, and an eighth magnetoresistor unit 108 form a second sensing branch SE2. The second sensing branch SE2 is configured as a full-bridge structure.

The fifth magnetoresistor unit 105 is coupled in series with the sixth magnetoresistor unit 106, and an intermediate node between the fifth magnetoresistor unit 105 and the sixth magnetoresistor unit 106 is used as an output node, coupled to the signal processing circuit (specifically, coupled to the first signal processing circuit 401).

The seventh magnetoresistor unit 107 is coupled in series with the eighth magnetoresistor unit 108, and an intermediate node between the seventh magnetoresistor unit 107 and the eighth magnetoresistor unit 108 is used as an output node, coupled to the signal processing circuit (specifically, coupled to the first signal processing circuit 401).

For an embodiment shown in FIG. 19, the first magnetoresistor 201 and the second magnetoresistor 202 form the first sensing branch SE1. The first sensing branch SE1 is configured as a half-bridge structure.

The first magnetoresistor 201 is coupled in series with the second magnetoresistor 202, and an intermediate node between the first magnetoresistor 201 and the second magnetoresistor 202 is used as an output node, coupled to the signal processing circuit (specifically, coupled to a second signal processing circuit 402).

The seventh magnetoresistor 207 and the eighth magnetoresistor 208 form the second sensing branch SE2. The second sensing branch SE2 is configured as a half-bridge structure.

The seventh magnetoresistor 207 is coupled in series with the eighth magnetoresistor 208, and an intermediate node between the seventh magnetoresistor 207 and the eighth magnetoresistor 208 is used as an output node, coupled to the signal processing circuit (specifically, coupled to the second signal processing circuit 402).

Preferably, an intermediate node between the seventh magnetoresistor unit 107 and the eighth magnetoresistor unit 108 is coupled to the second signal processing circuit 402. In this way, by introducing an output of the angle sensor with a 180-degree output period into the second signal processing circuit 402, a component with a 180-degree output period in the carrier output formed by the half-bridge structure is canceled, so that the output of the magnetic field sensing module retains only a component with a 360-degree output period, facilitating subsequent matching of the sensing direction information and improving the output accuracy of the magnetic sensor.

For the embodiment shown in FIG. 20, the first magnetoresistor 201, second magnetoresistor 202, third magnetoresistor 203, and fourth magnetoresistor 204 form the first sensing branch RE1. The first sensing branch RE1 is configured as a full-bridge structure.

The first magnetoresistor 201 is coupled in series with the second magnetoresistor 202, and an intermediate node between the first magnetoresistor 201 and the second magnetoresistor 202 is used as an output node, coupled to the signal processing circuit (specifically, coupled to the second signal processing circuit 402).

The third magnetoresistor 203 is coupled in series with the fourth magnetoresistor 204, and an intermediate node between the third magnetoresistor 203 and the fourth magnetoresistor 204 is used as an output node, coupled to the signal processing circuit (specifically, coupled to the second signal processing circuit 402).

The fifth magnetoresistor 205, sixth magnetoresistor 206, seventh magnetoresistor 207, and eighth magnetoresistor 208 form the second sensing branch RE2. The second sensing branch RE2 is configured as a full-bridge structure.

The fifth magnetoresistor 205 is coupled in series with the sixth magnetoresistor 206, and an intermediate node between the fifth magnetoresistor 205 and the sixth magnetoresistor 206 is used as an output node, coupled to the signal processing circuit (specifically, coupled to the second signal processing circuit 402).

The seventh magnetoresistor 207 is coupled in series with the eighth magnetoresistor 208, and an intermediate node between the seventh magnetoresistor 207 and the eighth magnetoresistor 208 is used as an output node, coupled to the signal processing circuit (specifically, coupled to the second signal processing circuit 402).

Preferably, the intermediate node between the first magnetoresistor unit 101 and the second magnetoresistor unit 102 is coupled to the intermediate node of the first magnetoresistor 201 and the second magnetoresistor 202, together forming an output to the second signal processing circuit 402.

The intermediate node between the third magnetoresistor unit 103 and the fourth magnetoresistor unit 104 is coupled to the intermediate node of the third magnetoresistor 203 and the fourth magnetoresistor 204, together forming an output to the second signal processing circuit 402.

The intermediate node between the fifth magnetoresistor unit 105 and the sixth magnetoresistor unit 106 is coupled to the intermediate node of the fifth magnetoresistor 205 and the sixth magnetoresistor 206, together forming an output to the second signal processing circuit 402.

The intermediate node between the seventh magnetoresistor unit 107 and the eighth magnetoresistor unit 108 is coupled to the intermediate node between the seventh magnetoresistor 207 and the eighth magnetoresistor 208, together forming an output to the second signal processing circuit 402.

Refer to FIG. 17, FIG. 19, and FIG. 20, the magnetic sensor further includes an output module 404, configured to convert the received angle signals outputted by the output processing circuit 403 into a desired output mode, protocol, or format, thereby constituting a final angle output.

In summary, a magnetic field sensing module and the magnetic sensor provided by the present invention, on one hand, generate output in different sensitivity directions in response to a signal magnetic field by setting at least two groups of magnetoresistors with different current directions, and use these outputs together as the output; while applying the signal magnetic field to the magnetoresistors, different excitation magnetic fields are applied to different magnetoresistors, creating differences in magnetization directions among the magnetoresistors. Due to periodic variation of the signal magnetic field, the difference further enriches obtained magnetic signal content, especially allowing the acquisition of boundary points of an actual change period, thereby breaking the limitation of the magnetic field sensing module's own sensing period to support larger-period sensing.

It should be understood that although the description is given according to embodiments, it does not mean that each embodiment only contains one independent technical solution. The description method of the detailed description is only for clarity. Those skilled in the art should regard the detailed description as a whole, and the technical solutions in each embodiment can also be appropriately combined to form other embodiments understandable to those skilled in the art,

The series of detailed descriptions listed above are only specific descriptions of feasible embodiments of the present application and are not intended to limit the scope of protection of the present application. Any equivalent embodiments or changes made without departing from the spirit of the present application should be included within the scope of protection of the present application.

What is claimed is:

1. A magnetic field sensing module, comprising:
a first magnetoresistor and a second magnetoresistor coupled in series, forming an output node between the first magnetoresistor and the second magnetoresistor, where a first current direction at the first magnetoresistor and a second current direction at the second magnetoresistor are set at an angle;
in a first state, the first magnetoresistor is applied with a signal magnetic field carrying direction information and a first excitation magnetic field, and the second magnetoresistor is applied with the signal magnetic field and a second excitation magnetic field; in a second state, the first magnetoresistor is applied with the signal magnetic field and a third excitation magnetic field, and the second magnetoresistor is applied with the signal magnetic field and a fourth excitation magnetic field; a direction of the first excitation magnetic field is opposite to a direction of the third excitation magnetic field, and/or a direction of the second excitation magnetic field is opposite to a direction of the fourth excitation magnetic field.

2. The magnetic field sensing module according to claim 1, wherein actual direction information of the signal magnetic field is distributed within a first numerical interval, and sensing direction information of an angle sensor cooperating with the magnetic field sensing module is distributed within a second numerical interval; the range of the first numerical interval is greater than the range of the second numerical interval; an output node signal of the magnetic field sensing module is configured to match the sensing direction information to the first numerical interval.

3. The magnetic field sensing module according to claim 2, wherein the magnetic field sensing module forms a first output node signal in the first state and a second output node signal in the second state; a difference signal between the first output node signal and the second output node signal includes several zero crossings, configured to match the sensing direction information of the angle sensor to the first numerical interval; the first numerical interval includes a numerical interval from 0 degrees to 360 degrees.

4. The magnetic field sensing module according to claim 1, wherein a direction of the first excitation magnetic field and a direction of the third excitation magnetic field are perpendicular to the first current direction, and a direction of the second excitation magnetic field and a direction of the fourth excitation magnetic field is perpendicular to the second current direction.

5. The magnetic field sensing module according to claim 1, wherein the first current direction is perpendicular to the second current direction; a direction of the first excitation magnetic field is opposite to a direction of the third excitation magnetic field, and a direction of the second excitation magnetic field is the same as a direction of the fourth excitation magnetic field.

6. The magnetic field sensing module according to claim 1, wherein a direction of the first excitation magnetic field and a direction of the third excitation magnetic field are parallel to the first current direction, and a direction of the second excitation magnetic field and a direction of the fourth excitation magnetic field is perpendicular to the second current direction.

7. The magnetic field sensing module according to claim 1, wherein the first current direction is perpendicular to the second current direction; a direction of the first excitation magnetic field is opposite to a direction of the third excitation magnetic field, and a direction of the second excitation magnetic field is opposite to a direction of the fourth excitation magnetic field.

8. The magnetic field sensing module according to claim 1, wherein the first magnetoresistor comprises a first magnetoresistive element, a second magnetoresistive element, and a third magnetoresistive element, coupled in series and extending in a first direction, and the second magnetoresistor comprises a fourth magnetoresistive element, a fifth magnetoresistive element, and a sixth magnetoresistive element, coupled in series and extending in a second direction.

9. The magnetic field sensing module according to claim 1, wherein the magnetic field sensing module comprises a seventh magnetoresistor and an eighth magnetoresistor coupled in series, where the seventh magnetoresistor and the eighth magnetoresistor are coupled in parallel with the first magnetoresistor and the second magnetoresistor; the seventh current direction at the seventh magnetoresistor and the eighth current direction at the eighth magnetoresistor are set at an angle;
a first output node is set between the first magnetoresistor and the second magnetoresistor, and a fourth output node is set between the seventh magnetoresistor and the eighth magnetoresistor;
in the first state, the seventh magnetoresistor is applied with a signal magnetic field and a seventh excitation magnetic field, and the eighth magnetoresistor is applied with the signal magnetic field and an eighth excitation magnetic field; in the second state, the seventh magnetoresistor is applied with the signal magnetic field and a fifth excitation magnetic field, and the eighth magnetoresistor is applied with the signal magnetic field and a sixth excitation magnetic field; a direction of the fifth excitation magnetic field is opposite to a direction of the seventh excitation magnetic field, and/or a direction of the sixth excitation magnetic field is opposite to a direction of the eighth excitation magnetic field.

10. The magnetic field sensing module according to claim 9, wherein the first magnetoresistor and the second magnetoresistor are configured to form a first output node signal in the first state and the first magnetoresistor and the second magnetoresistor are configured to form a second output node signal in the second state; the seventh magnetoresistor and the eighth magnetoresistor are configured to form a fourth output node signal in the first state and the seventh magnetoresistor and the eighth magnetoresistor are configured to form a third output node signal in the second state; a first difference signal between the first output node signal and the second output node signal, and a second difference signal between the third output node signal and the fourth output node signal are configured to match the sensing direction information of an angle sensor corresponding to the magnetic field sensing module to the first numerical interval; the first numerical interval includes a numerical interval from 0 degrees to 360 degrees.

11. The magnetic field sensing module according to claim 9, wherein a direction of the fifth excitation magnetic field and a direction of the seventh excitation magnetic field are perpendicular to the seventh current direction, and a direction of the sixth excitation magnetic field and a direction of the eighth excitation magnetic field are parallel to the eighth current direction.

12. The magnetic field sensing module according to claim 9, wherein the seventh current direction is parallel to the first current direction, the seventh current direction is perpendicular to the eighth current direction; a direction of the fifth excitation magnetic field is opposite to a direction of the seventh excitation magnetic field, and a direction of the sixth excitation magnetic field is opposite to a direction of the eighth excitation magnetic field.

13. A magnetic field sensing module, comprising:
a first magnetoresistor and a second magnetoresistor coupled in series, forming a first output node between the first magnetoresistor and the second magnetoresistor, where a first current direction at the first magnetoresistor and a second current direction at the second magnetoresistor are set at an angle;
a third magnetoresistor and a fourth magnetoresistor coupled in series, forming a second output node between the third magnetoresistor and the fourth magnetoresistor, where a third current direction at the third magnetoresistor and a fourth current direction at the fourth magnetoresistor are set at an angle;
the third magnetoresistor and the fourth magnetoresistor are coupled in parallel with the first magnetoresistor and the second magnetoresistor;
the first magnetoresistor is applied with a signal magnetic field carrying direction information and a first excitation magnetic field, the second magnetoresistor is applied with the signal magnetic field and a second excitation magnetic field; the third magnetoresistor is applied with the signal magnetic field and a third excitation magnetic field, the fourth magnetoresistor is applied with the signal magnetic field and a fourth excitation magnetic field; a direction of the first excitation magnetic field is opposite to a direction of the third excitation magnetic field, and/or a direction of the second excitation magnetic field is opposite to a direction of the fourth excitation magnetic field.

14. The magnetic field sensing module according to claim 13, wherein actual direction information of the signal magnetic field is distributed within a first numerical interval, and sensing direction information of an angle sensor cooperating with the magnetic field sensing module is distributed within a second numerical interval; a range of the first numerical interval is greater than a range of the second numerical interval; an output node signal of the magnetic field sensing module is configured to match the sensing direction information to the first numerical interval.

15. The magnetic field sensing module according to claim 14, wherein the first magnetoresistor and the second magnetoresistor are configured to form a first output node signal, and the third magnetoresistor and the fourth magnetoresistor are configured to form a second output node signal; a difference signal between the first output node signal and the second output node signal includes several zero crossings, configured to match the sensing direction information of the angle sensor to the first numerical interval; the first numerical interval includes a numerical interval from 0 degrees to 360 degrees.

16. The magnetic field sensing module according to claim 13, wherein a direction of the first excitation magnetic field is parallel to the first current direction, a direction of the second excitation magnetic field is perpendicular to the second current direction, a direction of the third excitation magnetic field is parallel to the third current direction, and a direction of the fourth excitation magnetic field is perpendicular to the fourth current direction.

17. The magnetic field sensing module according to claim 13, wherein the first current direction is perpendicular to the second current direction; a direction of the first excitation magnetic field is opposite to a direction of the third excitation magnetic field, and a direction of the second excitation magnetic field is opposite to a direction of the fourth excitation magnetic field.

18. The magnetic field sensing module according to claim 13, wherein the first magnetoresistor comprises a first magnetoresistive element, a second magnetoresistive element, and a third magnetoresistive element, coupled in series and extending in a first direction, the second magnetoresistor comprises a fourth magnetoresistive element, a fifth magnetoresistive element, and a sixth magnetoresistive element, coupled in series and extending in a second direction; the third magnetoresistor comprises a seventh magnetoresistive element, an eighth magnetoresistive element, and a ninth magnetoresistive element, coupled in series and extending in the first direction, the fourth magnetoresistor comprises a tenth magnetoresistive element, an eleventh magnetoresistive element, and a twelfth magnetoresistive element, coupled in series and extending in the second direction.

19. The magnetic field sensing module according to claim 13, wherein the magnetic field sensing module comprises:
a fifth magnetoresistor and a sixth magnetoresistor coupled in series, forming a third output node between the fifth magnetoresistor and the sixth magnetoresistor, where a fifth current direction at the fifth magnetoresistor and a sixth current direction at the sixth magnetoresistor are set at an angle;
a seventh magnetoresistor and an eighth magnetoresistor coupled in series, forming a fourth output node between the seventh magnetoresistor and the eighth magnetoresistor, where a seventh current direction at the seventh magnetoresistor and an eighth current direction at the eighth magnetoresistor are set at an angle;
the seventh magnetoresistor and the eighth magnetoresistor are coupled in parallel with the fifth magnetoresistor and the sixth magnetoresistor;
the fifth magnetoresistor is applied with a signal magnetic field carrying direction information and a fifth excitation magnetic field, the sixth magnetoresistor is applied with the signal magnetic field and a sixth excitation magnetic field; the seventh magnetoresistor is applied with the signal magnetic field and a seventh excitation magnetic field, the eighth magnetoresistor is applied with the signal magnetic field and an eighth excitation magnetic field; a direction of the fifth excitation magnetic field is opposite to a direction of the seventh excitation magnetic field, and/or a direction of the sixth excitation magnetic field is opposite to a direction of the eighth excitation magnetic field.

20. The magnetic field sensing module according to claim 19, wherein the first magnetoresistor and the second magnetoresistor are configured to form a first output node signal, the third magnetoresistor and the fourth magnetoresistor are configured to form a second output node signal; the fifth magnetoresistor and the sixth magnetoresistor are configured to form a third output node signal, the seventh magnetoresistor and the eighth magnetoresistor are configured to form a fourth output node signal; a first difference signal between the first output node signal and the second output node signal, and a second difference signal between the third output node signal and the fourth output node signal are configured to match the sensing direction information of an angle sensor cooperating with the magnetic field sensing module to the first numerical interval;
the first numerical interval includes a numerical interval from 0 degrees to 360 degrees.

21. The magnetic field sensing module according to claim 19, wherein the direction of the fifth excitation magnetic field is perpendicular to the fifth current direction, the direction of the sixth excitation magnetic field is parallel to the sixth current direction, the direction of the seventh excitation magnetic field is perpendicular to the seventh current direction, and the direction of the eighth excitation magnetic field is parallel to the eighth current direction.

22. The magnetic field sensing module according to claim 19, wherein the fifth current direction is parallel to the first current direction, the fifth current direction is perpendicular to the sixth current direction, and the seventh current direction is perpendicular to the eighth current direction; the direction of the fifth excitation magnetic field is opposite to the direction of the seventh excitation magnetic field, and the direction of the sixth excitation magnetic field is opposite to the direction of the eighth excitation magnetic field.

23. The magnetic field sensing module according to claim 19, wherein the direction of the first excitation magnetic field is the same as the direction of the second excitation magnetic field, the direction of the third excitation magnetic field is the same as the direction of the fourth excitation magnetic field, the direction of the fifth excitation magnetic field is the same as the direction of the sixth excitation magnetic field, and the direction of the seventh excitation magnetic field is the same as the direction of the eighth excitation magnetic field.

24. A magnetic sensor, comprising a magnetic field sensing module according to claim 1 and an excitation coil for generating an excitation magnetic field at the magnetic field sensing module; a magnetoresistive element in the magnetic field sensing module is arranged in a first direction or a second direction, and the excitation coil is arranged on at least one side of the magnetic field sensing module in a third direction; the third direction is perpendicular to both the first direction and the second direction.

25. The magnetic sensor according to claim 24, wherein the magnetic field sensing module is formed on a first side of a substrate, and the excitation coil comprises a first coil arranged on a side of the magnetic field sensing module close to the substrate; an isolation layer is arranged between the first coil and the magnetic field sensing module.

26. The magnetic sensor according to claim 24, wherein the excitation coil comprises a first coil and a second coil arranged on both sides of the magnetic field sensing module in the third direction; the current directions at the conductor sections of the first coil and the second coil with a same projection position on a side of the magnetic field sensing module are opposite.

27. The magnetic sensor according to claim 24, wherein the magnetic field sensing module comprises a first magnetoresistor and a second magnetoresistor coupled in series and arranged on one side of the geometric center of the magnetic field sensing module in an opposite direction of the first direction, the second magnetoresistor and the first magnetoresistor are arranged at intervals in the second direction; the magnetic field sensing module comprises a third magnetoresistor and a fourth magnetoresistor coupled in series and arranged on one side of the geometric center of the magnetic field sensing module in the first direction, the fourth magnetoresistor and the third magnetoresistor are arranged at intervals in the second direction;
the magnetic field sensing module comprises a fifth magnetoresistor and a sixth magnetoresistor coupled in series and arranged on one side of the geometric center of the magnetic field sensing module in an opposite direction of the second direction, the fifth magnetoresistor and the sixth magnetoresistor are arranged at intervals in the first direction; the magnetic field sensing module comprises a seventh magnetoresistor and an eighth magnetoresistor coupled in series and arranged on one side of the geometric center of the magnetic field sensing module in the second direction, the seventh magnetoresistor and the eighth magnetoresistor are arranged at intervals in the first direction;
the first direction and the second direction are perpendicular.

28. The magnetic sensor according to claim 27, wherein the magnetoresistive elements in the first magnetoresistor, the third magnetoresistor, the fifth magnetoresistor, and the seventh magnetoresistor extend along the first direction, and the magnetoresistive elements in the second magnetoresistor, the fourth magnetoresistor, the sixth magnetoresistor, and the eighth magnetoresistor extend along the second direction;
with the geometric center as the center, the first magnetoresistor, the second magnetoresistor, the fifth magnetoresistor, the sixth magnetoresistor, the fourth magnetoresistor, the third magnetoresistor, the eighth magnetoresistor, and the seventh magnetoresistor are arranged in a counterclockwise direction in sequence;
the excitation coil comprises a first coil, the first coil comprises a first conductor end arranged on a side of the magnetic field sensing module away from the geometric center of the magnetic field sensing module; the first coil extends from the first conductor end around the geometric center along the first direction or the second direction and extends close to the geometric center to form a second conductor end;
projection of a conductor section of the first coil between the first conductor end and the second conductor end on the magnetic field sensing module at least covers all magnetoresistive elements with a same extension direction as the conductor section;
the first magnetoresistor, the second magnetoresistor, the third magnetoresistor, the fourth magnetoresistor, the fifth magnetoresistor, the sixth magnetoresistor, the seventh magnetoresistor, and the eighth magnetoresistor surround and form a central space;
the magnetic sensor further comprises an angle sensor cooperating with the magnetic field sensing module, the angle sensor is arranged on a side of the magnetoresistor away from the geometric center.

29. A magnetic sensor, comprising:
an angle sensor, which obtains sensing direction information for a signal magnetic field distributed in a second numerical interval, and actual direction information of the signal magnetic field is distributed in a first numerical interval, where a range of the first numerical interval is greater than a range of the second numerical interval;
a magnetic field sensing module according to claim 1, configured to form a difference signal containing several zero crossings;
a signal processing circuit coupled to an output node of the magnetic field sensing module, configured at least to generate a square wave signal based on the difference signal; and
an output processing circuit coupled to the signal processing circuit, configured to match the sensing direction information to the first numerical interval based on the square wave signal, so that the sensing direction information is consistent with the actual direction information.

30. The magnetic sensor according to claim 29, wherein the magnetic field sensing module comprises a seventh magnetoresistor and an eighth magnetoresistor; a first output node is set between the first magnetoresistor and the second magnetoresistor, and a fourth output node is set between the seventh magnetoresistor and the eighth magnetoresistor;
the first output node is configured to form a first difference signal, and the fourth output node is configured to form a second difference signal; a phase difference is configured between the first difference signal and the second difference signal;
the signal processing circuit is configured to form a first square wave signal based on the high and low levels of the first difference signal relative to a preset voltage threshold, and to form a second square wave signal based on the high and low levels of the second difference signal relative to the preset voltage threshold;
the output processing circuit is configured to output the sensing direction information when a sensed angle value falls into a first angle range of the second numerical interval and the first square wave signal is at a high level; and/or, to add a sensed angle value to a length of the second numerical interval and output the sum value when the sensed angle value falls into a first angle range of the second numerical interval and the first square wave signal is at a low level; and/or,
to output the sensing direction information when a sensed angle value falls into a second angle range of the second numerical interval and the second square wave signal is at a high level; and/or, to add a sensed angle value to a length of the second numerical interval and output the sum value when the sensed angle value falls into a second angle range of the second numerical interval and the second square wave signal is at a low level; and/or,
to add a sensed angle value to a length of the second numerical interval and output the sum value when the sensed angle value falls into a third angle range of the second numerical interval and the first square wave signal is at a high level; and/or, to output the sensing direction information when a sensed angle value falls into a third angle range of the second numerical interval and the first square wave signal is at a low level;
wherein the sensing direction information carries the sensed angle value;
the first numerical interval is from 0 degrees to 360 degrees, the second numerical interval is from 0 degrees to 180 degrees, and the phase difference between the first difference signal and the second difference signal is 90 degrees.
